(19) United States
(12) Patent Application Publication
(10) Pub. No.: US 2025/0017040 A1
(43) Pub. Date: Jan. 9, 2025

(54) DISPLAY PANEL AND ELECTRONIC APPARATUS

(71) Applicant: Samsung Display Co., Ltd., Yongin-si (KR)

(72) Inventors: Chanyoung Kim, Yongin-si (KR); Sangwoo Kang, Yongin-si (KR); Seongmin Cho, Yongin-si (KR); Seongyong Hwang, Yongin-si (KR)

(21) Appl. No.: 18/432,301

(22) Filed: Feb. 5, 2024

(30) Foreign Application Priority Data
Jul. 5, 2023 (KR) 10-2023-0087398

(51) Int. Cl. H10K 59/121; H10K 59/122; H10K 59/38; H10K 59/40; H10K 59/80; H10K 102/00

(52) U.S. Cl. CPC H10K 59/121; H10K 59/122; H10K 59/38; H10K 59/40; H10K 59/8792; H10K 2102/311

(57) ABSTRACT

A display panel includes a display area including a substrate including emission areas in a flat display area and in a bending display area bending outside the flat display area, and a transmission area between adjacent emission areas in the bending display area, a pixel circuit layer on the substrate and including a pixel circuit, a light-emitting diode, a bank layer defining a first bank opening portion covering an edge of the first electrode and overlapping the first electrode, and defining a second bank opening portion corresponding to the transmission area, and a light-blocking layer on the bank layer, and defining a transmissive opening portion corresponding to the transmission area, wherein a central point of the transmissive opening portion of the light-blocking layer is closer to the flat display area than a central point of the second bank opening portion.

### CROSS-REFERENCE TO RELATED APPLICATION

The present application claims priority to, and the benefit of, Korean Patent Application No. 10-2023-0087398, filed on Jul. 5, 2023, in the Korean Intellectual Property Office, the entire disclosure of which is incorporated herein by reference.

### BACKGROUND

### 1. Field

One or more embodiments relate to a display panel, and an electronic apparatus including the same.

### 2. Description of the Related Art

Recently, the usage of display panels has diversified. In addition, display panels have become thinner and lighter, and thus, the range of use of display panels has expanded.

As the area occupied by a display area in display panels has increased, various functions connected to or associated with display panels have been added. As a method of adding various functions while expanding the display area, research has been steadily conducted on a display panel that has an area inside the display area, to add various functions except for image displaying.

### SUMMARY

To add various functions, a component, such as a camera or a sensor, may be arranged. To arrange the component while securing an increased area of a display area, the component may be arranged to overlap the display area. As a method of arranging the component, a display panel may include a transmission area transmitting a wavelength of, for example, light or sound. The disclosure provides a display panel having the structure described above and an electronic apparatus including the display panel.

Additional aspects will be set forth in part in the description which follows and, in part, will be apparent from the description, or may be learned by practice of the presented embodiments of the disclosure.

According to one or more embodiments, a display panel includes a display area including a flat display area, and a bending display area bending outside the flat display area, a peripheral area outside the display area, a substrate including emission areas in the flat display area and in the bending display area, and a transmission area between adjacent ones of the emission areas in the bending display area, a pixel circuit layer on the substrate, and including a pixel circuit, a light-emitting diode including a first electrode on the pixel circuit layer, an emission layer on the first electrode, and a second electrode on the emission layer, a bank layer covering an edge of the first electrode, defining a first bank opening portion overlapping the first electrode, and defining a second bank opening portion corresponding to the transmission area, and a light-blocking layer on the bank layer, and defining a transmissive opening portion corresponding to the transmission area, wherein a central point of the transmissive opening portion of the light-blocking layer is closer to the flat display area than a central point of the second bank opening portion.

The transmissive opening portion may be defined by a sidewall of the light-blocking layer including a first sidewall and a second sidewall, the first sidewall being adjacent to the flat display area based on a first virtual central line crossing the central point of the second bank opening portion, and the second sidewall being adjacent to the peripheral area based on the first virtual central line, wherein a first distance between the first sidewall and the first virtual central line is greater than a second distance between the second sidewall and the first virtual central line.

A partial area of the transmissive opening portion may overlap the second bank opening portion.

An entire area of the transmissive opening portion may overlap the second bank opening portion.

The bending display area may include a first bending area adjacent to the flat display area, and a second bending area outside the first bending area, wherein a difference between the first distance and the second distance is greater in the second bending area than in the first bending area.

The bending display area may include a first bending area adjacent to the flat display area, a second bending area outside the first bending area, and a third bending area outside the second bending area, wherein a difference between the first distance and the second distance is greater in the second bending area than in the first bending area, and is greater in the third bending area than in the second bending area.

The pixel circuit layer may further include lines including a first line and a second line, the first line being adjacent to the transmission area in a direction away from a first virtual central line crossing the central point of the second bank opening portion toward the flat display area, and the second line being adjacent to the transmission area in a direction away from the first virtual central line toward the peripheral area, wherein a third distance between the first virtual central line and the first line is less than a fourth distance between the first virtual central line and the second line.

The bending display area may include a first bending area adjacent to the flat display area, and a second bending area outside the first bending area, wherein a difference between the fourth distance and the third distance is greater in the second bending area than in the first bending area.

The flat display area may include a first edge, a second edge, a third edge, and a fourth edge, wherein the bending display area includes a first side display area, a second side display area, a third side display area, and a fourth side display area that are bent by respectively extending from the first edge, the second edge, the third edge, and the fourth edge, and wherein the transmission area is in the first side display area.

A size of the transmissive opening portion may be greater than a size of the second bank opening portion.

A size of the transmissive opening portion may be less than a size of the second bank opening portion.

The display panel may further include an input-sensing layer between the bank layer and the light-blocking layer, and including touch electrodes including a conductive mesh pattern defining mesh holes, wherein one of the emission areas in the bending display area and the transmission area are in a same mesh hole.

The display panel may further include color filters in a first opening, a second opening, and a third opening overlapping the emission areas and defined by the light-blocking layer.

According to one or more embodiments, a display panel includes a display area, including a flat display area, and a bending display area bending outside the flat display area, a peripheral area outside the display area, a substrate including emission areas in the flat display area and in the bending display area, and a transmission area between adjacent ones of the emission areas in the bending display area, a pixel circuit layer on the substrate, and including a pixel circuit, a light-emitting diode including a first electrode on the pixel circuit layer, an emission layer on the first electrode, and a second electrode on the emission layer, a bank layer covering an edge of the first electrode, defining a first bank opening portion overlapping the first electrode, and defining a second bank opening portion corresponding to the transmission area, an input-sensing layer on the bank layer and including touch electrodes, and a light-blocking layer on the input-sensing layer, and defining a transmissive opening portion corresponding to the transmission area, wherein the touch electrodes include a conductive mesh pattern defining mesh holes, and wherein one of the emission areas in the bending display area and the transmission area are in a same mesh hole.

According to one or more embodiments, an electronic apparatus includes a display panel, the display panel including a display area including a flat display area, and a bending display area bending outside the flat display area, a peripheral area outside the display area, a component below the display panel and in the bending display area, a substrate including emission areas in the flat display area and the bending display area, and a transmission area between adjacent ones of the emission areas in the bending display area, a pixel circuit layer on the substrate, and including a pixel circuit, a light-emitting diode including a first electrode on the pixel circuit layer, an emission layer on the first electrode, and a second electrode on the emission layer, a bank layer covering an edge of the first electrode, defining a first bank opening portion overlapping the first electrode, and defining a second bank opening portion corresponding to the transmission area, and a light-blocking layer on the bank layer, and defining a first opening, a second opening, a third opening overlapping the emission areas, and defining a transmissive opening portion corresponding to the transmission area, wherein a central point of the transmissive opening portion is closer to the flat display area than a first virtual central line crossing a central point of the second bank opening portion.

The transmissive opening portion may be defined by a sidewall of the light-blocking layer including a first sidewall adjacent to the flat display area based on the first virtual central line, and a second sidewall adjacent to the peripheral area based on the first virtual central line, wherein a first distance between the first sidewall and the first virtual central line is greater than a second distance between the second sidewall and the first virtual central line.

The bending display area may include a first bending area adjacent to the flat display area, and a second bending area closer to the peripheral area than the first bending area, wherein a difference between the first distance and the second distance is greater in the second bending area than in the first bending area.

The pixel circuit layer may further include lines including a first line below the bank layer and adjacent to the transmission area in a direction from the first virtual central line toward the flat display area, and a second line adjacent to the transmission area in a direction from the first virtual central line toward the peripheral area, wherein a third distance between the first virtual central line and the first line is less than a fourth distance between the first virtual central line and the second line.

The component may include a sensor using light.

The flat display area may include a first edge, a second edge, a third edge, and a fourth edge, wherein the bending display area includes a first side display area, a second side display area, a third side display area, and a fourth side display that are bent by respectively extending from the first edge, the second edge, the third edge, and the fourth edge, and wherein the transmission area is in the first side display area.

### BRIEF DESCRIPTION OF THE DRAWINGS

The above and other aspects of embodiments of the disclosure will be more apparent from the following description taken in conjunction with the accompanying drawings, in which:

FIG. 1 is a perspective view of an electronic apparatus according to one or more embodiments;

FIGS. 2A and 2B are schematic cross-sectional views of the electronic apparatus of FIG. 1;

FIG. 3 is a schematic plan view of a display panel according to one or more embodiments;

FIG. 4 is a cross-sectional view of a portion of an electronic apparatus according to one or more embodiments;

FIGS. 5A and 5B are cross-sectional views of a portion of an electronic apparatus according to one or more embodiments;

FIG. 6 is a plan view of an input-sensing layer of an electronic apparatus according to one or more embodiments;

FIG. 7 is a cross-sectional view of the input-sensing layer of FIG. 6 taken along the line VII-VII′;

FIG. 8 is an enlarged plan view of a region VIIIa of FIG. 6;

FIG. 9 is an enlarged plan view of a region VIIIb of FIG. 6;

FIG. 10 is a plan view of a region “A” or a region “B” of the display panel of FIG. 3, according to one or more embodiments;

FIG. 11 is a plan view of a region “C” of the display panel of FIG. 3, according to one or more embodiments;

FIG. 12 is an enlarged view of a region “E” of FIG. 11, according to one or more embodiments;

FIG. 13 is a cross-sectional view of a display panel according to one or more embodiments, taken along the line XI-XI′ of FIGS. 10 and 11;

FIG. 14 is a cross-sectional view of a display panel of FIG. 12 according to one or more embodiments, taken along the line XII-XII′ of FIG. 11;

FIG. 15 is a schematic cross-sectional view of a transmission area when a bending display area of the display panel of FIG. 14 is bent;

FIG. 16 is an enlarged view of the region “E” of FIG. 11, according to one or

more other embodiments;

FIG. 17 is a cross-sectional view of a display panel of FIG. 16 according to one or more embodiments, taken along the line XII-XII′ of FIG. 11;

FIG. 18 is a schematic cross-sectional view of a display panel according to one or more embodiments;

FIGS. 19 and 20 are views of transmission areas in a first bending area and a second bending area, respectively, according to one or more embodiments of FIG. 18, the transmission areas corresponding to the region “E” of FIG. 11;

FIG. 21 is a plan view of the region “C” of the display panel of FIG. 3, according to one or more other embodiments;

FIG. 22 is an enlarged view of a region “F” of FIG. 21, according to one or more embodiments; and

FIG. 23 is an enlarged view of the region “F” of FIG. 21, according to one or more other embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

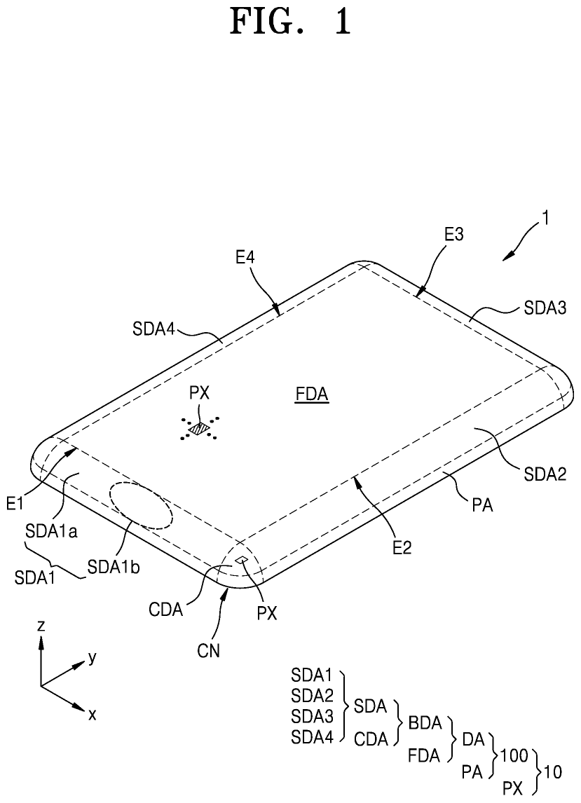

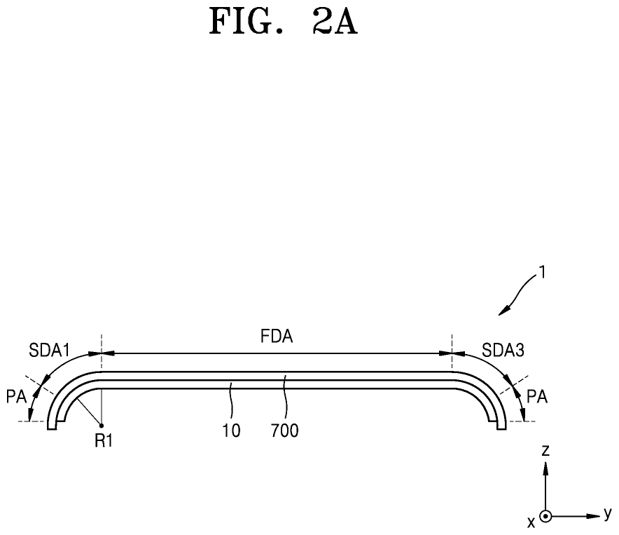

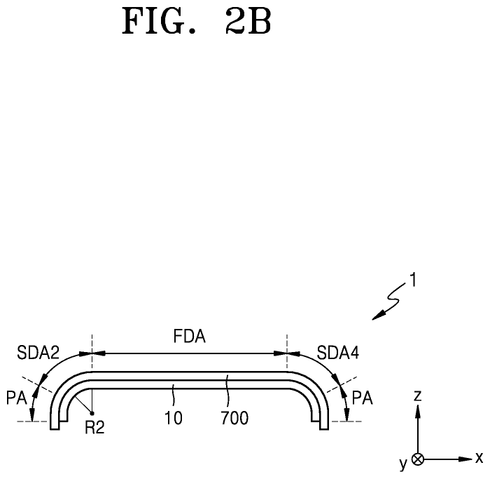

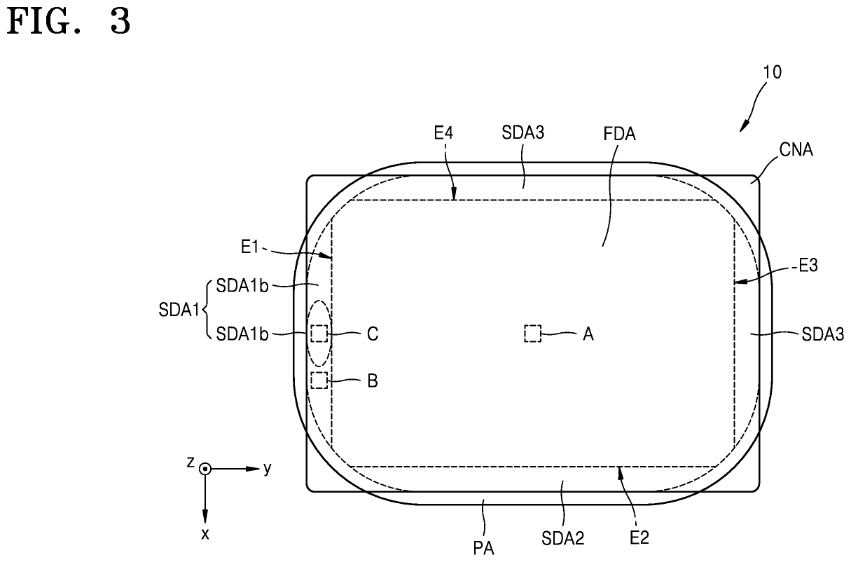

FIG. 1 is a perspective view of an electronic apparatus 1 according to one or more embodiments. FIGS. 2A and 2B are schematic cross-sectional views of the electronic apparatus 1 of FIG. 1. FIG. 3 is a schematic plan view of a display panel 10 according to one or more embodiments. FIGS. 1 to 2B illustrate a bent state of the display panel 10, and FIG. 3 illustrates an unbent state of the display panel 10.

Referring to FIGS. 1 to 3, the electronic apparatus 1 may include the display panel 10 and a window 700.

The electronic apparatus 1 according to one or more embodiments may display a motion image or a static image, and may be used as a display screen of various products including not only portable electronic devices, such as a mobile phone, a smartphone, a tablet personal computer (PC), a mobile communication terminal, an electronic notebook, an electronic book, a portable multimedia player (PMP), a navigation device, and a ultra mobile PC (UMPC), but also television (TV), a notebook computer, a monitor, a signboard, the Internet of things, etc. Also, the electronic apparatus 1 according to one or more embodiments may be used in wearable devices, such as a smart watch, a watch phone, a glasses-type display, and a head-mounted display (HMD). Also, the electronic apparatus 1 according to one or more embodiments may be used as a center information display (CID) on a gauge of a vehicle or a center fascia or a dashboard of the vehicle, a room mirror display substituting a side-view mirror of a vehicle, or a display located on a rear surface of a front seat, as an entertainment device for a backseat of a vehicle. FIG. 1 illustrates the electronic apparatus 1 used as a smartphone, for convenience of explanation.

According to one or more embodiments, the electronic apparatus 1 may have a long side in a first direction, and a short side in a second direction. Here, the first direction and the second direction may cross each other. For example, the first direction and the second direction may make an acute angle with each other. As another example, the first direction and the second direction may make an obtuse angle or a right angle with each other. Hereinafter, a case in which the first direction (for example, a y direction or a −y direction) and the second direction (for example, an x direction or a −x direction) are orthogonal to each other is mainly described in detail.

According to one or more other embodiments, the electronic apparatus may have a side in the first direction (for example, the y direction or the −y direction) and a side in the second direction (for example, the x direction or the −x direction), the side in the first direction and the side in the second direction having the same length as each other. Also, according to one or more other embodiments, the electronic apparatus may have a short side in the first direction (for example, the y direction or the −y direction) and a long side in the second direction (for example, the x direction or the −x direction).

A corner at which the long side extending in the first direction (for example, the y direction or the −y direction) and the short side extending in the second direction (for example, the x direction or the −x direction) meet each other may be curved to have a curvature (e.g., predetermined curvature).

The display panel 10 may include a substrate 100 and a plurality of pixels PX. The substrate 100 or the display panel 10 including the substrate 100 may include, as illustrated in FIG. 1, a display area DA for displaying an image, and a peripheral area PA outside the display area DA.

The plurality of pixels PX may be arranged in the display area DA, and an image may be displayed through the plurality of pixels PX. Each of the plurality of pixels PX may include sub-pixels. For example, each of the plurality of pixels PX may include a red sub-pixel, a green sub-pixel, and a blue sub-pixel. Alternatively, each of the plurality of pixels PX may include a red sub-pixel, a green sub-pixel, a blue sub-pixel, and a white sub-pixel.

The display area DA may include a flat display area FDA and a bending display area BDA. The flat display area FDA may have a flat upper surface. The bending display area BDA may be arranged at an outer portion of the flat display area FDA, and may include a curved surface that is bent by extending from the flat display area FDA.

The plurality of pixels PX arranged in each display area DA may display an image. According to one or more embodiments, a pixel PX including a display element may be arranged in the flat display area FDA. According to one or more embodiments, a pixel PX including a display element may be arranged in the bending display area BDA. According to one or more embodiments, the pixels PX in the flat display area FDA and in the bending display area BDA may provide separate images.

The bending display area BDA may include a side display area SDA and a corner display area CDA. According to one or more embodiments, a pixel PX including a display element may be arranged in the side display area SDA. According to one or more embodiments, a pixel PX including a display element may be arranged in the corner display area CDA. According to one or more embodiments, the pixels PX in the side display area SDA and in the corner display area CDA may provide separate images.

The side display area SDA may be arranged at a side surface of the flat display area FDA with a corner CN therebetween. According to one or more embodiments, the side display area SDA may include a first side display area SDA1, a second side display area SDA2, a third side display area SDA3, and a fourth side display area SDA4. According to some embodiments, at least one of the first side display area SDA1, the second side display area SDA2, the third side display area SDA3, and/or the fourth side display area SDA4 may be omitted.

The first side display area SDA1 and the third side display area SDA3 may be connected to the flat display area FDA in the first direction (for example, the y direction or the −y direction). For example, the first side display area SDA1 may be connected to the flat display area FDA in the −y direction, and the third side display area SDA3 may be connected to the flat display area FDA in the y direction.

The first side display area SDA1 and the third side display area SDA3 may be bent by having a curvature radius. According to one or more embodiments, the curvature radius of each of the first side display area SDA1 and the third side display area SDA3 may be different from each other. According to one or more other embodiments, the curvature radius of each of the first side display area SDA1 and the third side display area SDA3 may be the same as each other. Hereinafter, a case where the curvature radius of each of the first side display area SDA1 and the third side display area SDA3 is the same as a first curvature radius R1 (see FIG. 2A) is mainly described in detail. Also, the first side display area SDA1 and the third side display area SDA3 may be the same or substantially the same as each other, and thus, the first side display area SDA1 is mainly described in detail.

As illustrated in FIG. 2B, the second side display area SDA2 and the fourth side display area SDA4 may be connected to the flat display area FDA in the second direction (for example, the x direction or the −x direction). For example, the second side display area SDA2 may be connected to the flat display area FDA in the x direction, and the fourth side display area SDA4 may be connected to the flat display area FDA in the −x direction.

The second side display area SDA2 and the fourth side display area SDA4 may be bent by having a curvature radius. According to one or more embodiments, the curvature radius of each of the second side display area SDA2 and the fourth side display area SDA4 may be different from each other. According to one or more other embodiments, the curvature radius of each of the second side display area SDA2 and the fourth side display area SDA4 may be the same as each other. Hereinafter, a case where the curvature radius of each of the second side display area SDA2 and the fourth side display area SDA4 is the same as a second curvature radius R2 (see FIG. 2B) is mainly described in detail. Also, the second side display area SDA2 and the fourth side display area SDA4 may be the same or substantially the same as each other, and thus, the second side display area SDA2 is mainly described in detail.

According to one or more embodiments, the flat display area FDA may include a first edge E1, a second edge E2, a third edge E3, and a fourth edge E4. The first edge E1 and the third edge E3 may be arranged in parallel with each other while extending in the second direction (for example, the x direction or the −x direction). Each of the second edge E2 and the fourth edge E4 may be arranged perpendicularly to the first edge E1 and the third edge E3. The second edge E2 and the fourth edge E4 may be arranged in parallel with each other while extending in the first direction (for example, the y direction or the −y direction). According to one or more embodiments, the flat display area FDA may have a quadrangular shape including four edges. In this case, the first side display area SDA1 may be bent by extending from the first edge E1 of the flat display area FDA. Also, the second side display area SDA2 may be bent by extending from the second edge E2 of the flat display area FDA. Also, the third side display area SDA3 may be bent by extending from the third edge E3 of the flat display area FDA. Also, the fourth side display area SDA4 may be bent by extending from the fourth edge E4 of the flat display area FDA.

The corner display area CDA may be arranged at the corner CN of the display panel 10 and may be bent. That is, the corner display area CDA may be arranged to correspond to the corner CN. Here, the corner CN may be where the long side of the electronic apparatus 1 and/or the display panel 10 in the first direction (for example, the y direction or the −y direction) meets the short side of the electronic apparatus 1 and/or the display panel 10 in the second direction (for example, the x direction or the −x direction). The corner display area CDA may be arranged between adjacent side display areas SDA. For example, the corner display area CDA may be arranged between the first side display area SDA1 and the second side display area SDA2. Alternatively, the corner display area CDA may be arranged between the second side display area SDA2 and the third side display area SDA3, between the third side display area SDA3 and the fourth side display area SDA4, and/or between the fourth side display area SDA4 and the first side display area SDA1. Accordingly, the side display area SDA1 and the corner display area CDA may at least partially surround the flat display area FDA and may be bent.

According to one or more embodiments, the first side display area SDA1 may include a 1st-1 side display area SDA1a and a 1st-2 side display area SDA1b. The 1st-2 side display area SDA1b may be where a component for adding various functions to the electronic apparatus 1 is arranged, and may be referred to as a component area. The 1st-1 side display area SDA1 may be where a component is not arranged. FIGS. 1 and 3 illustrate that the 1st-2 side display area SDA1b, which is the component area, is arranged in the first side display area SDA1, but the disclosure is not limited thereto. For example, the component area where a component is arranged may be arranged in the bending display area BDA. For example, the component area may be arranged in one of the first side display area SDA1, the second side display area SDA2, the third side display area SDA3, and/or the fourth side display area SDA4. According to embodiments, for convenience of explanation, descriptions are given based on a case where the component area SDA1b is arranged in the first side display area SDA1 of the bending display area BDA.

The 1st-2 side display area SDA1b may be arranged between the peripheral area PA and the flat display area DA. According to one or more embodiments, it is illustrated that the 1st-2 side display area SDA1b may be arranged between the 1st-1 side display areas SDA1a. However, the 1st-2 side display area SDA1b is not limited thereto. For example, the 1st-2 side display area SDA1b may be surrounded by the 1st-1 side display area SDA1a. It is illustrated that the 1st-2 side display area SDA1b may have an elliptical shape in a plan view, but the 1st-2 side display area SDA1b is not limited thereto. For example, the 1st-2 side display area SDA1b may be modified to have various shapes including a quadrangular shape, a circular shape, an elliptical shape, etc.

The electronic apparatus 1 may display an image not only in the flat display area FDA, but also in the side display area SDA and the corner display area CDA. Thus, a ratio of the display area DA in the electronic apparatus 1 (e.g., a ratio of the area of the display area DA to the area of the peripheral area PA) may be increased.

The peripheral area PA may be an area where an image is not provided. The peripheral area PA may be arranged outside the display area DA, and may surround the display area DA. In the peripheral area PA, a driver, etc. for providing an electrical signal or power to display elements arranged in the display area DA may be arranged. A pad, which is an area to which an electronic element, a printed circuit board, etc. may be electrically connected, may be arranged in the peripheral area PA.

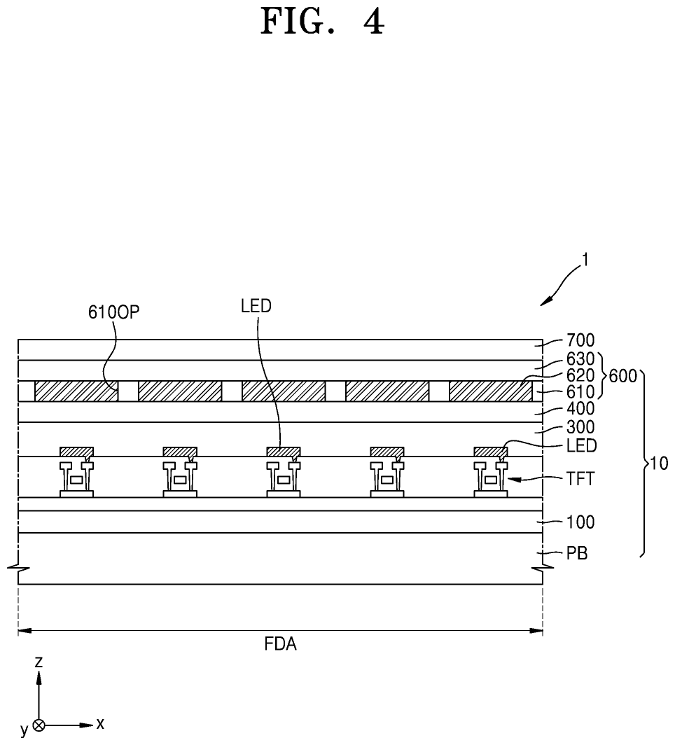

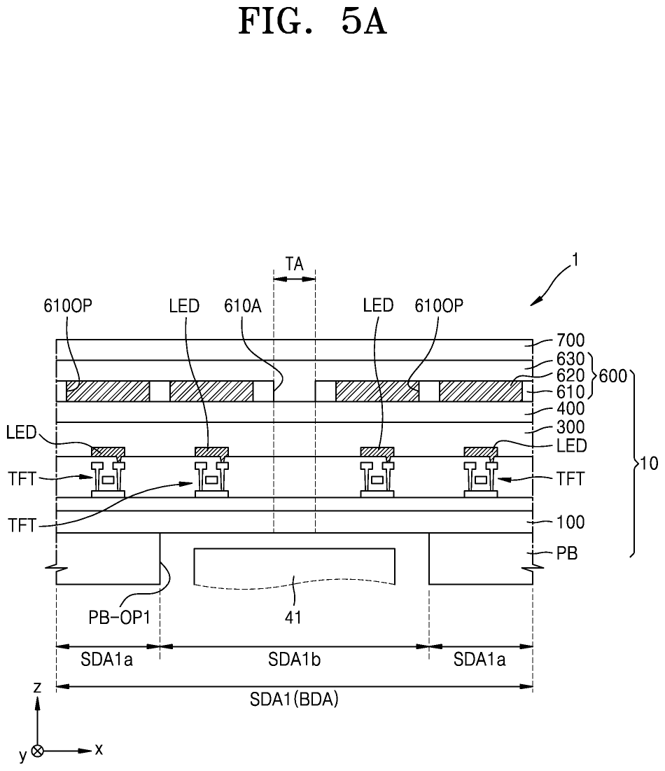

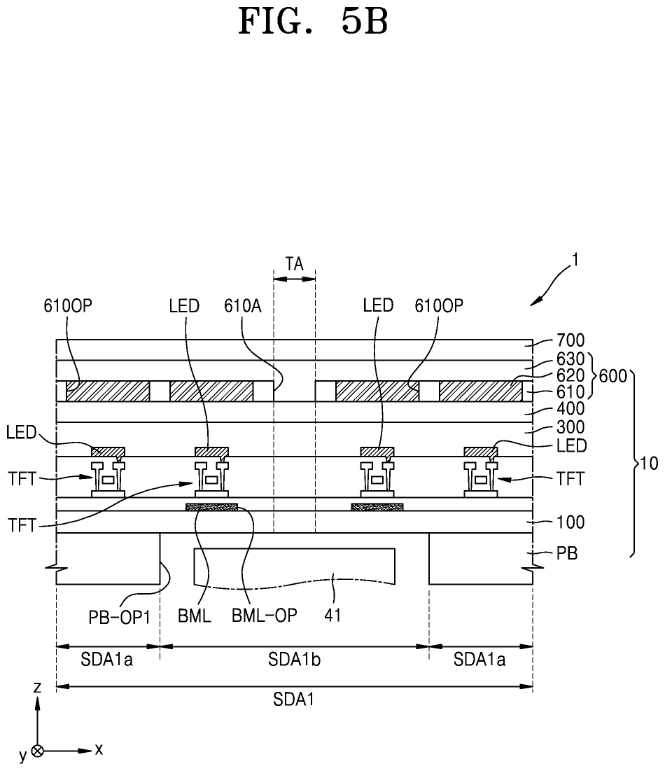

FIG. 4 is a cross-sectional view of a portion of the electronic apparatus 1 according to one or more embodiments. FIGS. 5A and 5B are cross-sectional views of a portion of the electronic apparatus 1 according to one or more embodiments. FIG. 4 illustrates a portion of the electronic apparatus 1 in the flat display area FDA, and FIGS. 5A and 5B illustrate a portion of the electronic apparatus 1 in the first side display area SDA1.

Referring to FIGS. 4, 5A, and 5B, the electronic apparatus 1 may include the display panel 10 and a component 41 located below the display panel 10 to overlap the display panel 10. In this specification, that A and B overlap each other denotes that A and B overlap each other in a direction (for example, a z direction) perpendicular to an upper surface of the substrate (e.g., overlap in plan view).

As illustrated in FIG. 4, the component 41 may not be arranged in the flat display area FDA.

According to embodiments, the component 41 may be arranged in the bending display area BDA. FIGS. 5A and 5B illustrate that the component 41 may be arranged in the first side display area SDA1 of the bending display area BDA. However, the component 41 is not limited thereto. For example, the component 41 may be arranged in one area from among the first side display area SDA1 (see FIG. 1), the second side display area SDA2 (see FIG. 1), the third side display area SDA3 (see FIG. 1), and the fourth side display area SDA4 (see FIG. 1). According to embodiments, a case where the component 41 is arranged in the 1st-2 side display area SDA1 of the bending display area BDA is mainly described, for convenience of explanation.

The 1st-2 side display area SDA1b may be the component area in which the component 41 is arranged, and the 1st-1 side display area SDA1a may be an area in which the component 41 is not arranged. According to one or more embodiments, when the component 41 is arranged in the first side display area SDA1, the remaining bending display areas BDA (e.g., the second side display area SDA2, the third side display area SDA3, and the fourth side display area SDA4) may have the same stack structure as the 1st-1 side display area SDA1a or the flat display area FDA.

The display panel 10 may include the substrate 100, a thin-film transistor TFT located on the substrate 100, a display element (for example, a light-emitting diode LED) electrically connected to the thin-film transistor TFT, an encapsulation layer 300 covering the display element, an input-sensing layer 400, a reflection prevention layer 600, and the window 700.

The substrate 100 may include glass or polymer resins. The substrate 100 including the polymer resins may be flexible, foldable, rollable, or bendable. The substrate 100 may have a layered structure including a layer including the polymer resins described above and an inorganic layer.

A lower protection film PB may be located on a lower surface of the substrate 100. The lower protection film PB may be coupled to the lower surface of the substrate 100. An adhesive layer may be arranged between the lower protection film PB and the substrate 100. Alternatively, the lower protection film PB may be directly formed on the lower surface of the substrate 100, and in this case, the adhesive layer may not be arranged between the lower protection film PB and the substrate 100.

The lower protection film PB may support and protect the substrate 100. The lower protection film PB may have an opening PB-OP1 corresponding to the 1st-2 side display area SDA1b. The lower protection film PB may include an organic insulating material, such as polyethylene terephthalate (PET) or polyimide (PI).

The thin-film transistor TFT and the light-emitting diode LED, which is a display element electrically connected to the thin-film transistor TFT, may be located on an upper surface of the substrate 100. The light-emitting diode LED may be an organic light-emitting diode including an organic material. The organic light-emitting diode may emit red, green, and blue light.

The light-emitting diode LED may be an inorganic light-emitting diode including an inorganic material. The inorganic light-emitting diode may include a PN junction diode including inorganic semiconductor-based materials. When a voltage is applied to the PN junction diode in a normal direction, holes and electrons may inject into the PN junction diode, and energy generated by recombination of the holes and the electrons may convert into light energy to emit light of a color (e.g., predetermined color). The inorganic light-emitting diode described above may have a width that is several to hundreds of micrometers or several to hundreds of nanometers. According to some embodiments, the light-emitting diode LED may include a quantum dot light-emitting diode. An emission layer of the light-emitting diode LED may include an organic material, an inorganic material, a quantum dot, an organic material and a quantum dot, or an inorganic material and a quantum dot.

The light-emitting diode LED may be electrically connected to the thin-film transistor TFT located therebelow. The thin-film transistor TFT and the light-emitting diode LED may be arranged in each of the flat display area FDA and the bending display area BDA. The thin-film transistor TFT and the light-emitting diode LED may be arranged in each of the flat display area FDA, the first to fourth side display areas SDA1 to SDA4, and the corner display area CDA.

The substrate 100, the display panel 10 including the substrate 100, or the electronic apparatus 1 including the display panel 10 may include a transmission area TA as illustrated in FIGS. 5A and 5B. The transmission area TA may be located in the 1st-2 side display area SDA1b in which the component is arranged. As illustrated in FIGS. 5A and 5B, the transmission area TA may be arranged between adjacent light-emitting diodes LED in the 1st-2 side display area SDA1b. In other words, the transmission area TA may be arranged between adjacent light-emitting diodes LED in the component area, in which the component 41 is arranged.

The transmission area TA may be an area transmitting light emitted from the component 41 and/or light toward the component 41. In the display panel 10, a transmission rate of the transmission area TA may be about at least 30%, about at least 40%, about at least 50%, about at least 60%, about at least 70%, about at least 75%, about at least 80%, about at least 85%, or about at least 90%.

The component 41 may include a sensor, such as a proximity sensor, an illumination sensor, an iris sensor, or a face recognition sensor, and/or may also include a camera (or an image sensor). The component 41 may use light. For example, the component 41 may emit and/or receive light of bands of infrared light, ultraviolet light, and visible light. A proximity sensor using infrared light may detect an object arranged to be near an upper surface of the electronic apparatus 1, and an illumination sensor may detect a brightness of light incident into the upper surface of the electronic apparatus 1. Also, an iris sensor may capture an image of an iris of a human arranged on the upper surface of the electronic apparatus 1, and a camera may receive light with respect to an object arranged on the upper surface of the electronic apparatus 1.

To reduce or prevent deterioration of a function of the thin-film transistor TFT arranged in the first side display area SDA1a, due to light transmitted by the transmission area TA, a light-blocking metal layer BML may be arranged between the substrate 100 and the thin-film transistor TFT. According to one or more embodiments, FIGS. 5A and 5B illustrate that the light-blocking metal layer BML may be arranged in the 1st-2 side display area SDA1b. The light-blocking metal layer BML may include an opening BML-OP corresponding to (overlapping) the transmission area TA. The light-blocking metal layer BML may not be arranged in the flat display area FDA, the 1st-1 side display area SDA1a, and the second to fourth side display areas SDA2 to SDA4 (see FIG. 1).

The encapsulation layer 300 may cover the light-emitting diodes LEDs. The encapsulation layer 300 may include at least one inorganic encapsulation layer and at least one organic encapsulation layer.

The input-sensing layer 400 may be formed on the encapsulation layer 300. The input-sensing layer 400 may obtain coordinate information according to an external input, for example, a touch event of a finger or of an object, such as a stylus pen. The input-sensing layer 400 may include a touch electrode and trace lines connected to the touch electrode. The input-sensing layer 400 may sense the external input by using a mutual cap method or a self-cap method.

The reflection prevention layer 600 may reduce the reflectivity of light (external light) incident toward the display panel 10 from the outside. The reflection prevention layer 600 may include a light-blocking layer 610, color filters 620, and an overcoat layer 630. The light-blocking layer 610 may include/define openings 610OP overlapping the light-emitting diode LEDs in the flat display area FDA and the bending display area BDA, and the color filters 620 may be arranged in the openings 610OP, respectively.

The light-blocking layer 610 may include/define a transmissive opening portion 610A corresponding to the transmission area TA (e.g., provided in the 1st-2 side display area SDA1b, as illustrated in FIGS. 5A and 5B).

The overcoat layer 630 may include a colorless transmissive material, and a portion of the overcoat layer 630 may at least partially fill the transmissive opening portion 610A.

The window 700 may be located on the reflection prevention layer 600. The window 700 may be coupled to the reflection prevention layer 600 via an adhesive layer, such as an optically clear adhesive (OCA). The window 700 may include a glass material or a plastic material. The glass material may include ultra-thin glass. The plastic material may include polyether sulfone, polyacrylate, polyether imide, polyethylene naphthalate, polyethylene terephthalate, polyphenylene sulfide, polyarylate, polyimide, polycarbonate, cellulose acetate propionate, or the like.

According to the disclosure, the component area, in which the component 41 is arranged, and the transmission area TA overlapping the component area, may be arranged in the bending display area BDA, and thus, the visibility of the display area DA in a front direction may be improved.

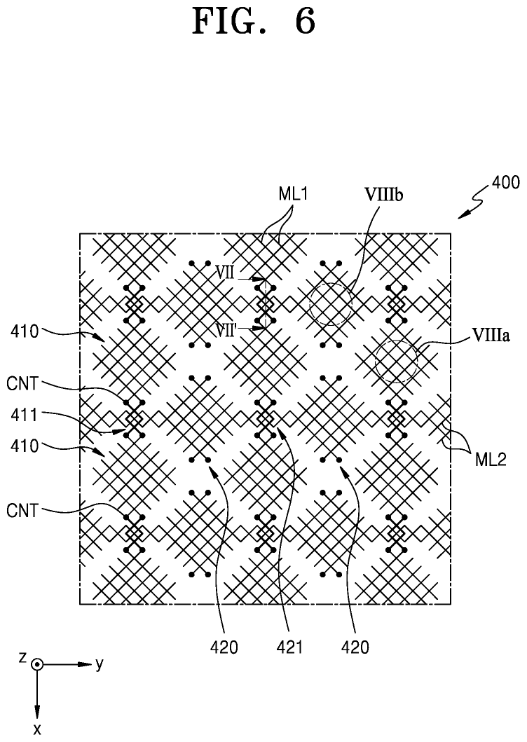

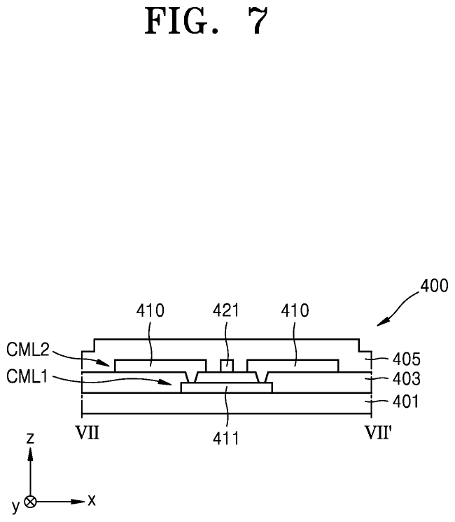

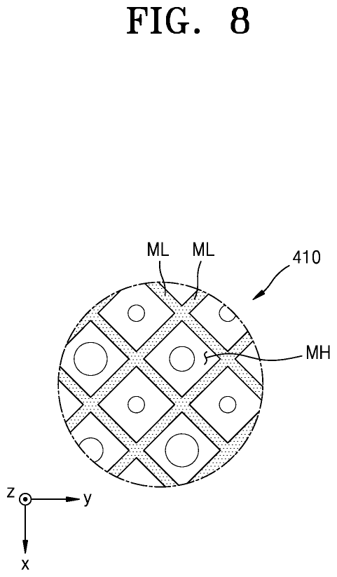

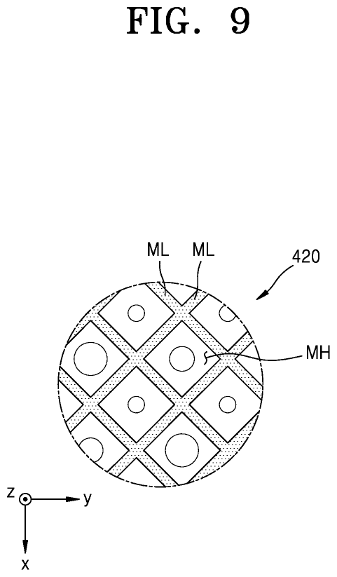

FIG. 6 is a plan view of the input-sensing layer 400 of the electronic apparatus 1 according to one or more embodiments. FIG. 7 is a cross-sectional view of the input-sensing layer 400 of FIG. 6 taken along the line VII-VII′. FIG. 8 is an enlarged plan view of a region VIIIa of FIG. 6. FIG. 9 is an enlarged plan view of a region VIIIb of FIG. 6.

The input-sensing layer 400 may include a plurality of touch electrodes. According to one or more embodiments, FIG. 6 illustrates that the touch electrodes may include first touch electrodes 410 and second touch electrodes 420. The first touch electrodes 410 and the second touch electrodes 420 may be arranged in the display area to cross each other.

The first touch electrodes 410 may be arranged in the x direction, and the second touch electrodes 420 may be arranged in the y direction crossing the x direction. The first touch electrodes 410 arranged in the x direction may be connected to each other by a first connection electrode 411 between the adjacent first touch electrodes 410. The second touch electrodes 420 arranged in the y direction may be connected to each other by a second connection electrode 421 between the adjacent second touch electrodes 420.

The first touch electrodes 410 and the second touch electrodes 420 may have conductive mesh patterns as illustrated in FIGS. 6, 8, and 9. For example, the conductive mesh pattern of the first touch electrode 410 may include a conductive line ML1 (hereinafter, referred to as a first conductive line), and the conductive mesh pattern of the second touch electrode 420 may include a conductive line ML2 (hereinafter, referred to as a second conductive line) insulated from the first conductive line ML1. The first conductive line ML1 and the second conductive line ML2 may include Mo, Mb, Ag, Ti, Cu, Al, and an alloy thereof.

Each of the first touch electrode 410 and the second touch electrode 420 may have the conductive mesh pattern, and thus, may include/define a hole (hereinafter, referred to as a mesh hole MH) as illustrated in FIGS. 8 and 9. The mesh holes MH may be defined by being completely surrounded respectively by the conductive lines corresponding thereto, and may be arranged to be apart from each other.

Like the first touch electrode 410 and the second touch electrode 420, the first connection electrode 411 and the second connection electrode 412 may include conductive lines of conductive mesh patterns. The conductive lines of the first and second connection electrodes 411 and 412 may also include mesh holes as illustrated in FIGS. 8 and 9.

As illustrated in FIG. 7, the input-sensing layer 400 may include a first touch insulating layer 401, a first conductive layer CML1, a second touch insulating layer 403, a second conductive layer CML2, and a third touch insulating layer 405. The first conductive layer CML1 may include the first connection electrode 411, and the second conductive layer CML2 may include the first touch electrode 410, the second touch electrode 420, and the second connection electrode 421. According to one or more other embodiments, any one of the first and second touch electrodes 410 and 420 may be provided on the first conductive layer CML1, and the other may be provided on the second conductive layer CML2. The first to third touch insulating layers 401, 403, and 405 may include an insulating material. According to one or more embodiments, the first to third touch insulating layers 401, 403, and 405 may include an inorganic insulating material, such as silicon oxide, silicon nitride, and/or silicon oxynitride. According to one or more other embodiments, at least one of the first, second, or third touch insulating layers 401, 403, or 405 may include an organic insulating material.

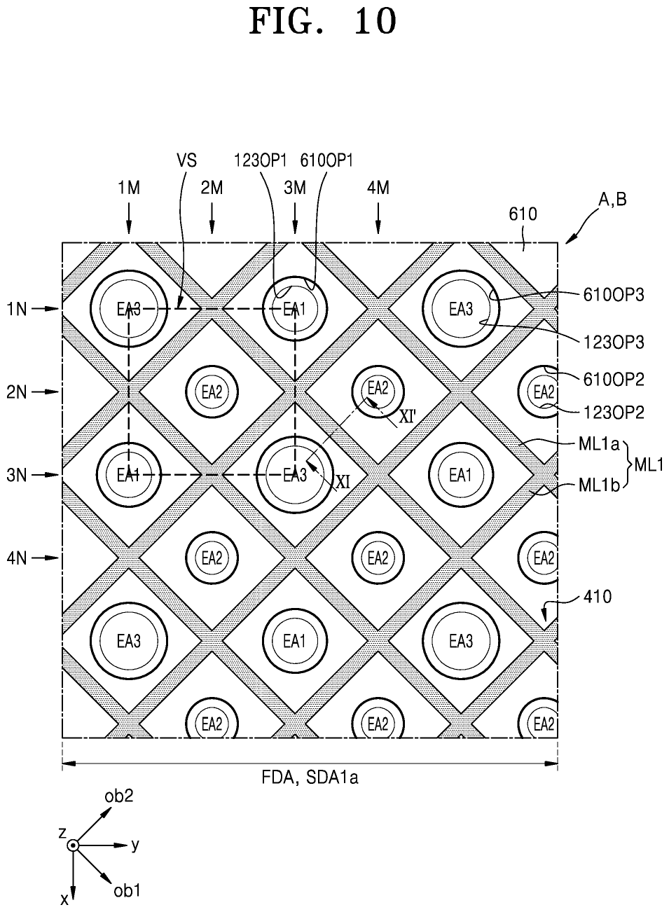

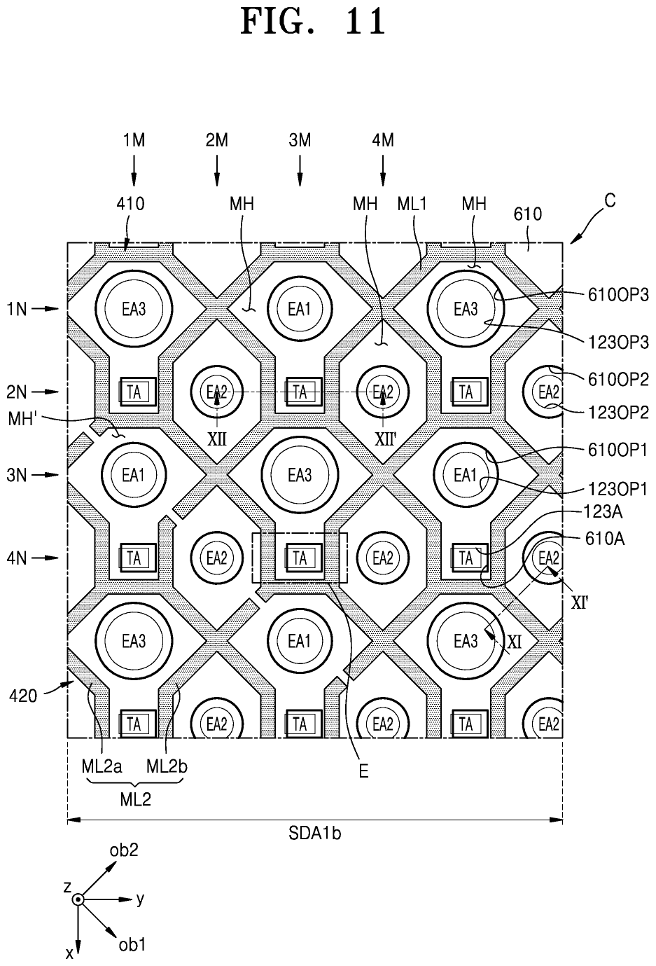

FIG. 10 is a plan view of a region “A” or a region “B” of the display panel 10 of FIG. 3, according to one or more embodiments. FIG. 11 is a plan view of a region “C” of the display panel 10 of FIG. 3, according to one or more embodiments.

Referring to FIG. 10, the substrate 100 (see FIG. 1), or the display panel 10 (see FIG. 1) including the substrate 100, may include a plurality of emission areas (e.g., first to third emission areas EA1, EA2, and EA3). The first to third emission areas EA1 to EA3 may be located in the flat display area FDA and the 1st-1 side display area SDA1a. The first to third emission areas EA1, EA2, and EA3 may emit different colors of light from one another by using light-emitting diodes. One of the first to third emission areas EA1, EA2, and EA3 may correspond to a red emission area, another may correspond to a green emission area, and the other may correspond to a blue emission area.

Sizes of the first to third emission areas EA1, EA2, and EA3 may respectively be defined by a plurality of openings included in a bank layer. For example, the first emission area EA1 may be defined by a first opening 123OP1 of the bank layer, the second emission area EA2 may be defined by a second opening 123OP2 of the bank layer, and the third emission area EA3 may be defined by a third opening 123OP3 of the bank layer. The first to third openings 123OP1 to 123OP3 defining the first to third emission areas EA1 to EA3 may be referred to as a first bank opening portion.

The first to third emission areas EA1, EA2, and EA3 may be arranged as a PENTILE™ type, for example, a diamond PENTILE™ type (PENTILE™ being a registered trademark of Samsung Display Co., Ltd., Republic of Korea). The third emission areas EA3 and the first emission areas EA1 may be alternately located in a first row 1N in the x direction, the second emission areas EA2 may be apart from each other in a second row 2N adjacent to the first row 1N, the first emission areas EA1 and the third emission areas EA3 may be alternately located in a third row 3N adjacent to the second row 2N, and the second emission areas EA2 may be apart from each other in a fourth row 4N adjacent to the third row 3N, wherein these arrangements of the first to third emission areas E1, E2, and E3 may be repeated to an nth row. Here, the size (or a width) of the third emission area EA3 and the first emission area EA1 may be greater than the size (or a width) of the second emission area EA2.

The third emission areas EA3 and the first emission areas EA1 located in the first row 1N may be misaligned with, or shifted from, the second emissions area EA2 located in the second row 2N. Thus, the third emission areas EA3 and the first emission areas EA1 may be alternately located in a first column 1M, the second emission areas EA2 may be apart from each other in a second column 2M adjacent to the first column 1M, the first emission areas EA1 and the third emission areas EA3 may be alternately located in a third column 3M adjacent to the second column 2M, and the second emission areas EA2 may be apart from each other in a fourth column 4M adjacent to the third column 3M, wherein these arrangements of the first to third emission areas E1, E2, and E3 may be repeated to an mth column.

To express these arrangements of the first to third emission areas EA1, EA2, and EA3 in a different way, the first emission areas EA1 may be located at a first vertex and a third vertex that diagonally face each other of a virtual square VS, a center point of which corresponds to a center point of the second emission area EA2, and the third emission areas EA3 may be located at a second vertex and a fourth vertex that are the other vertexes of the virtual square VS. Here, the virtual square VS may be variously modified to have a rectangular shape, a diamond shape, a square shape, etc.

These arrangements of the first to third emission areas EA1, EA2, and EA3 may be referred to as a PENTILET matrix structure or a PENTILE™ structure (e.g., a RGBG matrix structure, a PENTILE™ matrix structure, a PENTILE™ structure, or an RGBG structure, PENTILE™ being a registered trademark of Samsung Display Co., Ltd., Republic of Korea). By implementing rendering that represents a color by sharing adjacent emission areas, high resolution may be realized with a small number of emission areas.

Referring to FIG. 11, the first emission areas EA1, second emission areas EA2, and third emission areas EA3 emitting different colors of light from one another may be located in the 1st-2 side display area SDA1b. The sizes of the first to third emission areas EA1, EA2, and EA3 may be respectively defined by the first to third openings 123OP1, 123OP2, and 123OP3 of the bank layer, as described above.

The 1st-1 side display area SDA1a and the 1st-2 side display area SDA1b may have the same resolution as each other. For example, based on the same area, the arrangement, the aperture ratio, and/or the number of the first to third emission areas EA1, EA2, and EA3 in the 1st-2 side display area SDA1b may be the same as the arrangement, the aperture ratio, and/or the number of the first to third emission areas EA1 to EA3 in the 1st-1 side display area SDA1a. Each of the emission areas (e.g., the first to third emission areas EA1, EA2, and EA3) may include a light-emitting diode. Accordingly, that the arrangement and/or the number of the emission areas are respectively the same may denote that the arrangement and/or the number of the light-emitting diodes are respectively the same. That is, based on the same area, the arrangement and/or the number of the light-emitting diodes arranged in the 1st-1 side display area SDA1a may be the same as the arrangement and/or the number of the light-emitting diodes arranged in the 1st-2 side display area SDA1b. The flat display area FDA and the 1st-2 side display area SDA1b may have the same resolution as each other.

The 1st-2 side display area SDA1b may include the transmission area TA unlike the 1st-1 side display area SDA1a. The transmission area TA may be arranged between adjacent emission areas. According to some embodiments, the transmission area TA may be located in any one of two adjacent rows in a row direction (the x direction) and located in any one of two adjacent columns in a column direction (the y direction). For example, as illustrated in FIG. 11, the transmission area TA may be located in a second row 2N and a fourth row 4N and a first column 1M and a third column 3M. The bank layer may include a light-blocking material described above. Thus, the bank layer may include a second bank opening portion 123A corresponding to the transmission area TA as illustrated in FIG. 11.

Referring to FIGS. 10 and 11, each emission area EA1, EA2, or EA3 may be surrounded by a conductive line of a touch electrode. As illustrated in FIGS. 10 and 11, the touch electrode, for example, the first touch electrode 410, may include the conductive mesh pattern including the first conductive line ML1. The first conductive line ML1 may include a first sub-conductive line ML1a extending in a first diagonal direction ob1 (a direction forming an acute angle with the x direction and the y direction), and may include a second sub-conductive line ML1b extending in a second diagonal direction ob2 (a direction crossing the first diagonal direction). The plurality of mesh holes MH may be formed by crossing structures of the first sub-conductive lines ML1a and the second sub-conductive lines ML1b that are integrally formed with each other. Each of the mesh holes MH may have a boundary line of a closed-loop shape, and the mesh holes MH may be apart from each other in a plan view, and spatially separated from each other.

According to some embodiments, as illustrated in FIG. 11, the second touch electrode 420 may be arranged in the 1st-2 side display area SDA1b. The second touch electrode 420 may include the conductive mesh pattern including the second conductive line ML2. For example, the second conductive line ML2 may include a first sub-conductive line ML2a extending in the first diagonal direction ob1, and a second sub-conductive line ML2b extending in the second diagonal direction ob2. The plurality of mesh holes MH may be formed by crossing structures of the first sub-conductive lines ML2a and the second sub-conductive lines ML2b of the second conductive lines ML2, which are integrally formed with each other. Each of the mesh holes MH of the second touch electrodes 420 may have a boundary line of a closed-loop shape, and the mesh holes MH may be apart from each other in a plan view and spatially separated from each other. It is illustrated that the second touch electrode 420 is arranged in the 1st-2 side display area SDA1b. However, it is only an example, and the second touch electrode 420 may be arranged in the flat display area FDA and/or the 1st-1 side display area SDA1a.

The first touch electrode 410 and the second touch electrode 420 may be electrically insulated from each other. FIG. 11 illustrates that the first touch electrode 410 and the second touch electrode 420 may be physically spaced apart from each other. The emission area located in a space between the first touch electrode 410 and the second touch electrode 420, that is, some of the first and second emission areas EA1 and EA2 illustrated in FIG. 11, may be located in a spaced hole MH′ formed between a portion of the second conductive line ML2 and an adjacent portion of the first conductive line ML1. The spaced hole MH′ may be defined by a portion of the first conductive line ML1 and a portion of the second conductive line ML2, and the spaced holes MH′ adjacent to each other may be spatially connected to each other in a plan view.

In the 1st-2 side display area SDA1b, the transmission area TA may be located in the same mesh hole MH as any one emission area. With respect to this aspect, FIG. 11 illustrates that the first emission area EA1 and the transmission area TA may be located in the same mesh hole MH, and the third emission area EA3 and the transmission area TA may be located in the same mesh hole MH. The first emission area EA1 and the transmission area TA located in the same mesh hole MH may be, in a plan view, completely surrounded by a portion of the conductive line, for example, the first conductive line ML1, of the touch electrode. Likewise, the third emission area EA3 and the transmission area TA located in the same mesh hole MH may be, in a plan view, completely surrounded by a portion of the conductive line, for example, the first conductive line ML1, of the touch electrode.

The transmission area TA may be arranged while the 1st-1 side display area SDA1a and the 1st-2 side display area SDA1b may maintain the same resolution (for example, the number and/or an area of the emission areas based on the same area), and thus, a size and a planar shape of each mesh hole MH located in the 1st-2 side display area SDA1b may be different from a size and a planar shape of each mesh hole MH located in the 1st-1 side display area SDA1a. According to one or more embodiments, the mesh hole MH in which the second emission area EA2 is located as illustrated in FIG. 11 may correspond to a mesh hole MH in which the transmission area TA is not included, and thus, a size (or a width) of the mesh hole MH in which the second emission area EA2 of the 1st-2 side display area SDA1b is located may be less than a size (or a width) of the mesh hole MH in which the second emission area EA2 of the 1st-1 side display area SDA1a is located as illustrated in FIG. 10.

The light-blocking layer 610 may be arranged on the touch electrodes of FIGS. 10 and 11. The light-blocking layer 610 may cover the conductive lines of the touch electrodes (for example, the first and second touch electrodes 410 and 420) and may include/define openings or opening portions corresponding to the first to third emission areas EA1 to EA3 and the transmission area TA. With respect to this aspect, FIGS. 10 and 11 illustrate that the light-blocking layer 610 may include first to third openings 610OP1, 610OP2, and 610OP3 and the transmissive opening portion 610A, wherein the first to third openings 610OP1 to 610OP3 may respectively correspond to the first to third emission areas EA1 to EA3 arranged in the 1st-1 side display area SDA1a and the 1st-2 side display area SDA1b, and the transmissive opening portion 610A may correspond to the transmission area TA.

In a plan view, the first to third openings 610OP1, 610OP2, and 610OP3 of the light-blocking layer 610 may be apart from one another, and may overlap the first to third openings 123OP1, 123OP2, and 123OP3 of the bank layer, respectively, the first to third openings 123OP1, 123OP2, and 123OP3 of the bank layer defining the first to third emission areas EA1, EA2, and EA3, respectively. Sizes (or widths) of the first to third openings 610OP1, 610OP2, and 610OP3 of the light-blocking layer 610 may be greater than sizes (or widths) of the first to third openings 123OP1, 123OP2, and 123OP3 of the bank layer. The first to third openings 123OP1 to 123OP3 may cover an edge of a first electrode 210 described below, and each of the first to third openings 123OP1 to 123OP3 may overlap the first electrode 210.

In a plan view, at least a portion of the transmissive opening portion 610A of the light-blocking layer 610 may overlap the second bank opening portion 123A of the bank layer. According to one or more embodiments, a size (or a width) of the transmissive opening portion 610A of the light-blocking layer 610 may be greater than a size (or a width) of the second bank opening portion 123A of the bank layer.

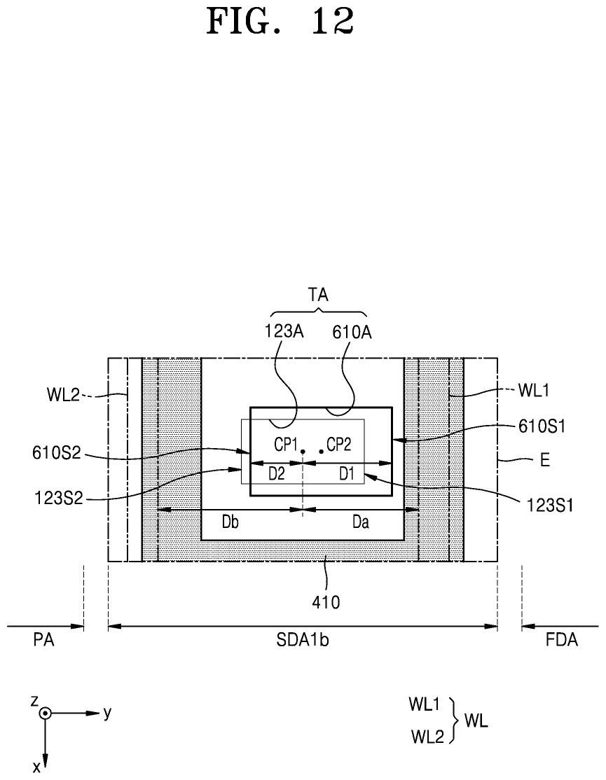

FIG. 12 is an enlarged view of a region “E” of FIG. 11, according to one or more embodiments. FIG. 12 is the enlarged view based on an unbent display panel.

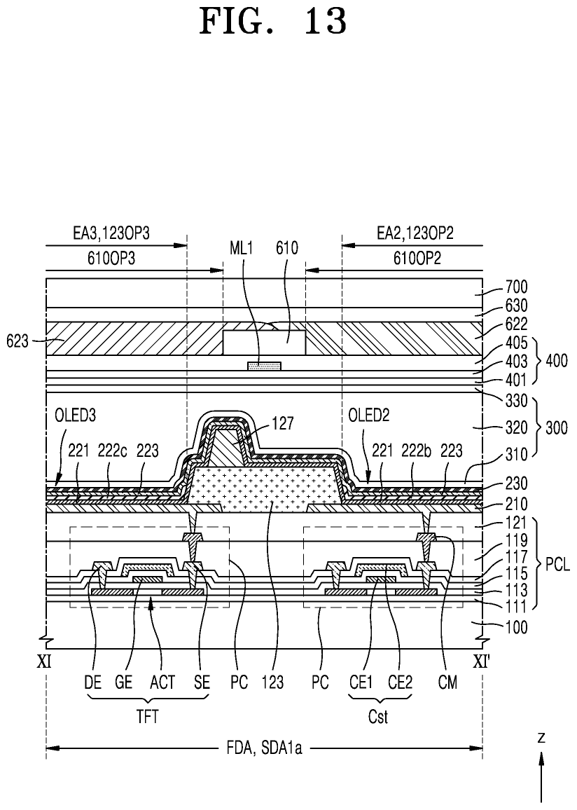

FIG. 13 is a cross-sectional view of a display panel according to one or more embodiments, taken along the line XI-XI′ of FIGS. 10 and 11.

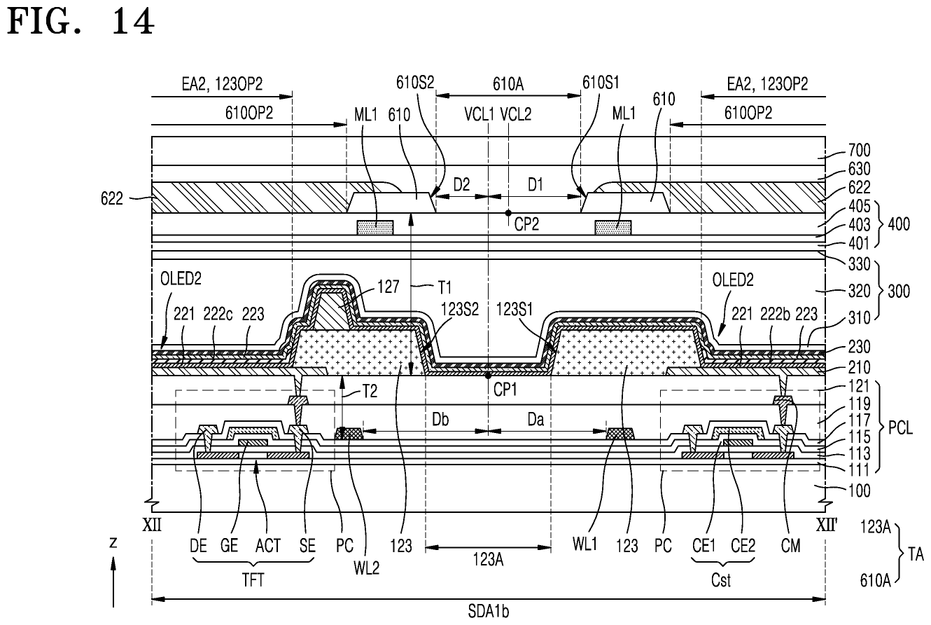

FIG. 14 is a cross-sectional view of the display panel of FIG. 12 according to one or more embodiments, taken along the line XII-XII′ of FIG. 11. FIG. 14 is the cross-sectional view of the display panel in the unbent state.

FIG. 13 illustrates a cross-sectional structure of adjacent emission areas in the flat display area FDA or the 1st-1 side display area SDA1a, and illustrates the second emission area EA2 and the third emission area EA3 as examples. FIG. 13 illustrates a case in which the second emission area EA2 of the display panel may emit light by using a second organic light-emitting diode OLED2, and the third emission area EA3 may emit light by using a third organic light-emitting diode OLED3.

Referring to FIG. 13, the second organic light-emitting diode OLED2 and the third organic light-emitting diode OLED3 may be formed on the substrate 100.

The substrate 100 may include a glass material or polymer resins. When the substrate 100 includes polymer resins, the substrate 100 may include a stack structure including a base layer including the polymer resins, and a barrier layer including an inorganic insulating material.

A pixel circuit layer PCL may be arranged on the substrate 100. The pixel circuit layer PCL may include a pixel circuit PC, a buffer layer 111, and an insulating structure including a gate-insulating layer 113, a first interlayer insulating layer 115, a second interlayer insulating layer 117, a first organic insulating layer 119, and a second organic insulating layer 121. According to one or more embodiments, the pixel circuit layer PCL may further include a plurality of lines.

The buffer layer 111 may be arranged on the substrate 100. The buffer layer 111 may reduce or prevent the penetration of impurities, moisture, or external substances from below the substrate 100. The buffer layer 111 may include an inorganic insulating material, such as silicon oxide, silicon oxynitride, and silicon nitride, and may include a single layer or layers including the inorganic insulating materials described above.

Each of the second organic light-emitting diode OLED2 and the third organic light-emitting diode OLED3 may be electrically connected to the pixel circuit PC. The second organic light-emitting diode OLED2 may be electrically connected to the pixel circuit PC between the substrate 100 and the second organic light-emitting diode OLED2, and the third organic light-emitting diode OLED3 may be electrically connected to the pixel circuit PC between the substrate 100 and the third organic light-emitting diode OLED3.

Each pixel circuit PC may include a thin-film transistor TFT and a storage capacitor Cst. The thin-film transistor TFT may include a semiconductor layer ACT, a gate electrode GE overlapping a channel area of the semiconductor layer ACT, and a source electrode SE and a drain electrode DE connected to a source area and a drain area of the semiconductor layer ACT, respectively. The gate-insulating layer 113 may be located between the semiconductor layer ACT and the gate electrode GE, and the first interlayer insulating layer 115 and the second interlayer insulating layer 117 may be located between the gate electrode GE and the source electrode SE, and/or between the gate electrode GE and the drain electrode DE.

The storage capacitor Cst may overlap the thin-film transistor TFT. The storage capacitor Cst may include a lower electrode CE1 and an upper electrode CE2 overlapping each other. According to some embodiments, the gate electrode GE of the thin-film transistor TFT may include, or may be, the lower electrode CE1 of the storage capacitor Cst. The first interlayer insulating layer 115 may be located between the lower electrode CE1 and the upper electrode CE2.

The semiconductor layer Act may include polysilicon. According to some embodiments, the semiconductor layer ACT may include amorphous silicon. According to some embodiments, the semiconductor layer ACT may include an oxide semiconductor of at least one material selected from the group consisting of In, Ga, Sn, Zr, V, Hf, Cd, Ge, Cr, Ti, or Zn. The semiconductor layer Act may include a channel area, and may include a source area and a drain area doped with impurities.

The gate-insulating layer 113 may include an inorganic insulating material, such as silicon oxide, silicon oxynitride, and silicon nitride, and may include a single layer or layers including the inorganic insulating materials described above.

The gate electrode GE or the lower electrode CE1 may include a low-resistance conductive material, such as Mo, Al, Cu, and/or Ti, and may include a single layer or layers including the materials described above.

The first interlayer insulating layer 115 may include an inorganic insulating material, such as silicon oxide, silicon oxynitride, and silicon nitride, and may include a single layer or layers including the materials described above.

The upper electrode CE2 may include Al, Pt, Pd, Ag, Mg, Au, Ni, Nd, Ir, Cr, Ca, Mo, Ti, W, and/or Cu, and may include a single layer or layers including the materials described above.

The second interlayer insulating layer 117 may include an inorganic insulating material, such as silicon oxide, silicon oxynitride, and silicon nitride, and may include a single layer or layers including the materials described above.

The source electrode SE and/or the drain electrode DE may include Al, Pt, Pd, Ag, Mg, Au, Ni, Nd, Ir, Cr, Ca, Mo, Ti, W, and/or Cu, and may include a single layer or layers including the materials described above. For example, the source electrode SE and/or the drain electrode DE may have a triple-layered structure including a Ti layer/an Al layer/a Ti layer.

The first organic insulating layer 119 may be located on the thin-film transistor TFT, and the thin-film transistor TFT may be electrically connected to the first electrode 210 of the organic light-emitting diode corresponding to the thin-film transistor TFT through a connection electrode CM located on the first organic insulating layer 119. The connection electrode CM may be connected to the thin-film transistor TFT through a contact hole of the first organic insulating layer 119, and the first electrode 210 may be connected to the connection electrode CM through a contact hole of the second organic insulating layer 121.

The first organic insulating layer 119 and/or the second organic insulating layer 121 may include an organic insulating material, such as acryl, benzocyclobutene (BCB), polyimide (PI), or hexamethyldisiloxane (HMDSO). According to some embodiments, the connection electrode CM and the second organic insulating layer 121 may be omitted. In this case, the first electrode 210 may be directly connected to the thin-film transistor TFT through the contact hole of the first organic insulating layer 119.

The second organic light-emitting diode OLED2 may include an overlapping structure of the first electrode 210, a second emission layer 222b, and a second electrode 230. The third organic light-emitting diode OLED3 may include an overlapping structure of the first electrode 210, a third emission layer 222c, and the second electrode 230. A first functional layer 221 and/or a second functional layer 223 may be included between the first electrode 210 and the second electrode 230.

The first electrode 210 may be located on the second organic insulating layer 121. The first electrode 210 may include a reflective layer including Ag, Mg, Al, Pt, Pd, Au, Ni, Nd, Ir, Cr, or a compound thereof. The first electrode 210 may include a reflective layer including the materials described above and a transparent conductive layer arranged above or/and below the reflective layer. The transparent conductive layer may include indium tin oxide (ITO), indium zinc oxide (IZO), zinc oxide (ZnO), indium oxide (In₂O₃), indium gallium oxide (IGO), or aluminum zinc oxide (AZO). According to one or more embodiments, the first electrode 210 may have a tri-layered structure of ITO/Ag/ITO layers.

The bank layer 123 may include a light-blocking material. The bank layer 123 may have, for example, a black color. For example, the bank layer 123 may include a PI-based binder and a pigment in which red, green, and blue colors are combined. Alternatively, the bank layer 123 may include a cardo-based binder resin and a mixture of a lactam-based black pigment and a blue pigment. Alternatively, the bank layer 123 may include carbon black. The bank layer 123 may reduce or prevent the penetration of external light along with the reflection prevention layer 600 to be described below and may increase a contrast of the display panel.

A spacer 127 may be located on the bank layer 123. The spacer 127 may include a material that is different from that of the bank layer 123. For example, while the bank layer 123 may include a negative photosensitive material, the spacer 127 may include a positive photosensitive material. Also, the bank layer 123 and the spacer 127 may be formed by separate mask processes.

The second emission layer 222b and the third emission layer 222c may correspond to the second opening 123OP2 and the third opening 123OP3 of the bank layer 123, respectively, and may overlap the first electrode 210. Each of the second emission layer 222b and the third emission layer 222c may include a high-molecular weight organic material or a low-molecular weight organic material for emitting light of a color (e.g., predetermined color), and the second emission layer 222b and the third emission layer 222c may emit light of respective colors that are different from each other. The first functional layer 221 and the second functional layer 223 may be respectively formed below and above the second emission layer 222b and the third emission layer 222c.

The first functional layer 221 may include a hole transport layer (HTL) and/or a hole injection layer (HIL). The second functional layer 223 may include an electron transport layer (ETL) and/or an electron injection layer (EIL). The first functional layer 221 and/or the second functional layer 223 may be formed throughout the substrate 100 unlike the emission layer 222. In other words, the first functional layer 221 and/or the second functional layer 223 may cover the flat display area FDA and the 1st-1 side display area SDA1a.

The second electrode 230 may include a material having a relatively high work function. For example, the second electrode 230 may include a transmissive thin-film including Ag and Mg.

The encapsulation layer 300 may cover the emission areas, for example, the second and third organic light-emitting diodes OLED2 and OLED3. According to one or more embodiments, the encapsulation layer 300 may include a first inorganic encapsulation layer 310, a second inorganic encapsulation layer 330, and an organic encapsulation layer 320 therebetween.

Each of the first and second inorganic encapsulation layers 310 and 330 may include at least one inorganic insulating material. The inorganic insulating material may include aluminum oxide, titanium oxide, tantalum oxide, hafnium oxide, zinc oxide, silicon oxide, silicon nitride, and/or silicon oxynitride.

The organic encapsulation layer 320 may include a polymer-based material. The polymer-based material may include acryl-based resins, epoxy-based resins, polyimide, polyethylene, etc. For example, the organic encapsulation layer 320 may include acryl-based resins, for example, polymethylmethacrylate, polyacrylic acid, etc. The organic encapsulation layer 320 may be formed by curing a monomer or coating a polymer.

The input-sensing layer 400 may include a first touch insulating layer 401 on the encapsulation layer 300, a second touch insulating layer 403 on the first touch insulating layer 401, and a third touch insulating layer 405 on the second touch insulating layer 403. The input-sensing layer 400 may include a touch electrode, wherein the touch electrode may include a conductive line located above the second touch insulating layer 403 and below the third touch insulating layer 405. With respect to this aspect, FIG. 14 illustrates the first conductive line ML1 according to one or more embodiments.

The conductive line, for example, the first conductive line ML1 of FIG. 14, may include Mo, Mb, Ag, Ti, Cu, Al, and/or an alloy thereof. The first conductive line ML1 may be covered by the light-blocking layer 610 having a greater width than the first conductive line ML1.

The light-blocking layer 610 may include the second opening 610OP2 and the third opening 610OP3 respectively overlapping the second and third emission areas EA2 and EA3. The second and third openings 610OP2 and 610OP3 of the light-blocking layer 610 may have greater sizes (or widths) than the second and third openings 123OP2 and 123OP3 of the bank layer 123, respectively.

A second color filter 622 and a third color filter 623 may be located in the second and third openings 610OP2 and 610OP3 of the light-blocking layer 610, respectively. The second and third color filters 622 and 623 may have colors corresponding to light emitted from the second and third emission areas EA2 and EA3, respectively. According to one or more embodiments, when the second emission area EA2 emits green light, the second color filter 622 may be a green color filter, and when the third emission area EA3 emits blue light, the third color filter 623 may be a blue color filter.

The overcoat layer 630 may be located on the light-blocking layer 610 and the color filters. The overcoat layer 630 may be a colorless transmissive layer not having colors of a visible light band, and may planarize an upper surface of the light-blocking layer 610 and upper surfaces of the color filters 620. The overcoat layer 630 may include a colorless transmissive organic material, such as acryl-based resins, and may be covered by the window 700.

FIG. 11 illustrates the region “C” of FIG. 3, wherein the peripheral area PA (see FIGS. 1 and 3) may be arranged on the left side (for example, the −y direction) of the region “C,” and the flat display area FDA (see FIGS. 1 and 3) may be arranged on the right side (for example, the y direction) of the region “C.” Accordingly, the peripheral area PA may be arranged on the left side of a region “E” illustrated in FIG. 12, which is an enlarged transmission area TA arranged in the region “C,” and the flat display area FDA may be arranged on the right side of the region “E.” Also, the peripheral area PA may be arranged on the left side, and the flat display area FDA may be arranged on the right side in the cross-sectional view of the 1st-2 side display area SDA1b illustrated in FIG. 14.

Referring to FIG. 14, in the 1st-2 side display area SDA1b, the transmission area TA may be arranged between two emission areas in a row direction (an x direction). According to one or more embodiments, as illustrated in FIGS. 11 and 14, the transmission area TA may be arranged between the second emission areas EA2 emitting the same color of light. The transmission area TA may be defined as an area where light may be transmitted through an overlapping portion of the second bank opening portion 123A of the bank layer 123 and through the transmissive opening portion 610A of the light-blocking layer 610.

The second organic light-emitting diodes OLED2 corresponding to the second emission areas EA2 may be arranged on the substrate 100 to be adjacent to each other. Each second organic light-emitting diode OLED2 may be electrically connected to the pixel circuit PC described above with reference to FIG. 13, and a detailed structure of the display panel may be the same as the structure described above with reference to FIG. 13. Thus, hereinafter, descriptions are given mainly based on differences.

According to one or more embodiments, the pixel circuit layer PCL arranged on the substrate 100 may further include a plurality of lines WL. The plurality of lines WL may include a first line WL1 and a second line WL2 arranged to be adjacent to the transmission area TA while not overlapping the transmission area TA. The plurality of lines WL may be arranged below the bank layer 123. The plurality of lines WL may be arranged between the substrate 100 and the bank layer 123. According to one or more embodiments, the plurality of lines WL may be arranged to overlap the bank layer 123. The plurality of lines WL may be covered by the bank layer 123, and may not be exposed to transmitted light.

In FIG. 14, it is illustrated that the plurality of lines WL may be arranged on the same layer as the source electrode SE and the drain electrode DE. However, the plurality of lines WL are not limited thereto. For example, the plurality of lines WL may be arranged on the same layer as the semiconductor layer ACT, the gate electrode GE, or the upper electrode CE2. As such, the arrangement of the plurality of lines WL may be variously modified.

The bank layer 123 may include/define the second openings 123OP2 defining the second emission areas EA2, and may include the second bank opening portion 123A located between the two second openings 123OP2 and corresponding to the transmission area TA.

The input-sensing layer 400 may be located on the encapsulation layer 300, and a portion of the conductive line included in the touch electrode of the input-sensing layer 400 may surround each emission area, as described above with reference to FIG. 11. With respect to this aspect, FIG. 14 illustrates the first conductive line ML1 overlapping a material portion of the bank layer 123 so as not to overlap the second opening 123OP2 of the bank layer 123. The first conductive line ML1 may overlap the material portion of the bank layer 123, and may also overlap the light-blocking layer 610.

The light-blocking layer 610 may include/define the second opening 610OP2 overlapping each second emission area EA2, and may include/define the transmissive opening portion 610A located between the two adjacent second openings 610OP2 and corresponding to the transmission area TA. The transmissive opening portion 610A may be at least partially filled with a portion of the overcoat layer 630.

A size (or a width) of the transmissive opening portion 610A of the light-blocking layer 610 may be different from a size (or a width) of the second bank opening portion 123A of the bank layer 123. For example, as illustrated in FIGS. 12 and 14, the size (or the width) of the transmissive opening portion 610A of the light-blocking layer 610 may be greater than the size (or the width) of the second bank opening portion 123A of the bank layer 123.

Referring to FIGS. 12 and 14 together, a central point CP2 of the transmissive opening portion 610A of the light-blocking layer 610 may be arranged to be closer to the flat display area FDA than a central point CP1 of the second bank opening portion 123A of the bank layer 123.

The second bank opening portion 123A may be defined by a sidewall of the bank layer 123. As illustrated in FIG. 14, the sidewall of the bank layer 123 may include a first sidewall 123S1 and a second sidewall 123S2 facing each other. The first sidewall 123S1 of the bank layer 123 may be arranged to be adjacent to the flat display area FDA, based on the central point CP1 of the second bank opening portion 123A. The second sidewall 123S2 of the bank layer 123 may be arranged to be adjacent to the peripheral area PA, based on the central point CP1 of the second bank opening portion 123A.

The transmissive opening portion 610A may be defined by a sidewall of the light-blocking layer 610. The sidewall of the light-blocking layer 610 may include a first sidewall 610S1 and a second sidewall 610S2 facing each other. The first sidewall 610S1 of the light-blocking layer 610 may be arranged to be adjacent to the flat display area FDA, based on a first virtual central line VCL1 crossing the central point CP1 of the second bank opening portion 123A. The second sidewall 610S2 of the light-blocking layer 610 may be arranged to be adjacent to the peripheral area PA, based on the first virtual central line VCL1 crossing the central point CP1 of the second bank opening portion 123A.

The central point CP2 of the transmissive opening portion 610A may be arranged to be closer to the flat display area FDA than the first virtual central line VCL1 of the bank layer 123. A second virtual central line VCL2 of the light-blocking layer 610 may be arranged to be closer to the flat display area FDA than the first virtual central line VCL1 of the bank layer 123. A distance D1 between the first sidewall 610S1 of the light-blocking layer 610 and the first virtual central line VCL1 may be greater than a distance D2 between the second sidewall 610S2 of the light-blocking layer 610 and the first virtual central line VCL1. In other words, the transmissive opening portion 610A of the light-blocking layer 610 may be shifted in a direction toward the flat display area FD more than the second bank opening portion 123A of the bank layer 123. When the transmissive opening portion 610A of the light-blocking layer 610 is formed in the bending display area BDA (see FIG. 1), the transmissive opening portion 610A may be shifted in a direction away from the peripheral area PA more than when the transmissive opening portion 610A of the light-blocking layer 610 is formed in the flat display area FDA.

FIGS. 12 and 14 illustrate that a partial area of the transmissive opening portion 610A of the light-blocking layer 610 overlaps the second bank opening portion 123A of the bank layer 123, but the transmissive opening portion 610A is not limited thereto. According to one or more other embodiments, the entire area of the transmissive opening portion 610A of the light-blocking layer 610 may overlap the second bank opening portion 123A of the bank layer 123.

According to one or more embodiments, the first sidewall 610S1 of the light-blocking layer 610 may be arranged to be closer to the flat display area FDA more than the first sidewall 123S1 of the bank layer 123. According to one or more embodiments, the second sidewall 123S2 of the bank layer 123 may be arranged to be closer to the peripheral area PA more than the second sidewall 610S2 of the light-blocking layer 610. A distance between the first sidewall 610S1 of the light-blocking layer 610 and the first virtual central line VCL1 may be greater than a distance between the first sidewall 123S1 of the bank layer 123 and the first virtual central line VCL1. A distance between the second sidewall 610S2 of the light-blocking layer 610 and the first virtual central line VCL1 may be less than a distance between the second sidewall 123S2 of the bank layer 123 and the first virtual central line VCL1.

The first line WL1 and the second line WL2 might not overlap the transmission area TA. The first line WL1 may be arranged to be adjacent to the transmission area TA in a direction from the first virtual central line VCL1 toward the flat display area FDA. The second line WL2 may be arranged to be adjacent to the transmission area TA in a direction from the first virtual central line VCL1 toward the peripheral area PA. A conductive layer including a conductive material may not be arranged between the first line WL1 and the second line WL2. For example, only an insulating layer may be arranged between the first line WL1 and the second line WL2. The transmission area TA may be where an area between the first line WL1 and the second line WL2, the second bank opening portion 123A, and the transmissive opening portion 610A overlap one another. That is, light incident to the display panel may be transmitted through the transmissive opening portion 610A, the second bank opening portion 123A, and the area between the first line WL1 and the second line WL2, and may be incident to the component 41 described with reference to FIGS. 5A and 5B.

A distance Da between the first line WL1 and the first virtual central line VCL1 may be less than a distance Db between the second line WL2 and the first virtual central line VCL1. When the second line WL2 is formed in the bending display area BDA, the second line WL2 may be shifted in a direction toward the peripheral area PA more than when the second line WL2 is formed in the flat display area FDA.

In this specification, the central point CP1 of the second bank opening portion 123A may be defined as a point arranged at the right center of the second bank opening portion 123A. In this specification, the central point CP2 of the transmissive opening portion 610A may be defined as a point arranged at the right center of the transmissive opening portion 610A.

In this specification, the first virtual central line VCL1 may be defined as a line crossing the central point CP1 of the second bank opening portion 123A, and arranged at the right center of the second bank opening portion 123A. The first virtual central line VCL1 may be arranged in a direction perpendicular to an upper surface of the substrate 100 (e.g., in a z direction).

In this specification, the second virtual central line VCL2 may be defined as a line crossing the central point CP2 of the transmissive opening portion 610A, and arranged at the right center of the transmissive opening portion 610A. The second virtual central line VCL2 may be arranged in a direction perpendicular to the upper surface of the substrate 100 (e.g., in a z direction).

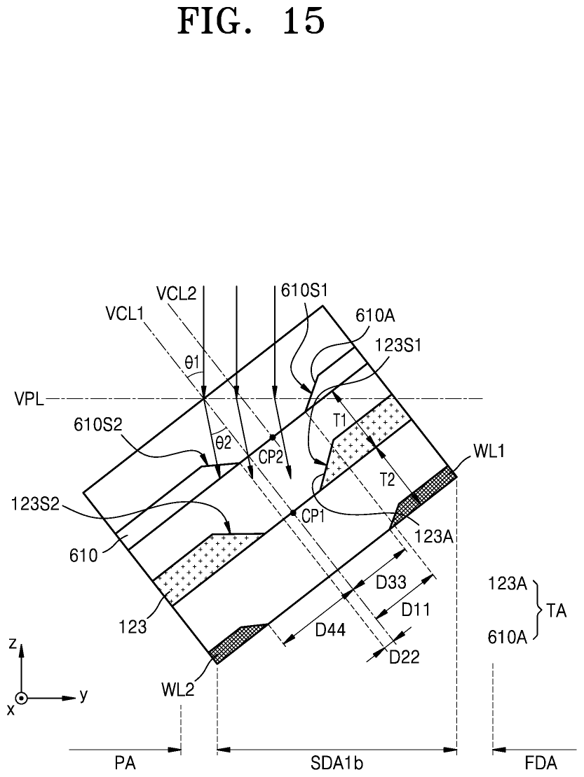

FIG. 15 is a schematic cross-sectional view of the transmission area TA arranged in the region “E” of FIG. 12, when the bending display area of the display panel is bent. FIG. 15 schematically illustrates a shape of the transmission area TA, when the transmission area TA is arranged in the 1st-2 side display area SDA1b, which is included in the bending display area BDA (see FIG. 1).

Referring to FIG. 15, light L incident to the display panel may be transmitted through the transmissive opening portion 610A, the second bank opening portion 123A, and an area between the first line WL1 and the second line WL2.

When the first virtual central line VCL1 of the second bank opening portion 123A and the second virtual central line VCL2 of the transmissive opening portion 610A are formed to correspond to each other, and when the display panel is bent, the amount of received light may be decreased due to overlapping portions of the light-blocking layer 610 and the bank layer 123, as compared to when the display panel is unbent. According to embodiments, the central point CP2 of the transmissive opening portion 610A may be shifted in a direction toward the flat display area FDA more than the first virtual central line VCL1 of the second bank opening portion 123A, and thus, the amount of received light of the component 41 (see FIGS. 5A and 5B) may be increased. Similarly, the second line WL2 may be relatively shifted in a direction toward the peripheral area PA, and thus, the amount of received light of the component 41 (see FIGS. 5A and 5B) may be increased.

When the bending display area of the display panel is bent, the first virtual central line VCL1 may be arranged in a direction perpendicular to a normal line of a curved surface of the display panel. When the bending display area of the display panel is bent, the second virtual central line VCL2 may be arranged in the direction perpendicular to the normal line of the curved surface of the display panel. A virtual horizontal line VPL illustrated in FIG. 15 may be parallel to an upper surface of the substrate 100 in the flat display area FDA. For example, the virtual horizontal line VPL may extend in a y direction.

An incident angle of incident light L may be θ1 and a refraction angle may be θ2. For example, θ1 may be an angle between a path of light incident toward the overcoat layer 630 (see FIG. 14) and the first virtual central line VCL1. For example, θ2 may be an angle between a path of light incident to the overcoat layer 630 (see FIG. 14) by being refracted and the first virtual central line VCL1. A difference value between a distance D11 between the first sidewall 610S1 of the light-blocking layer 610 and the first virtual central line VCL1, and a distance D22 between the second sidewall 610S2 of the light-blocking layer 610 and the first virtual central line VCL1, may be about equal to twice a value obtained by multiplying tan θ2 by a distance T1 between a lower surface of the bank layer 123 and a lower surface of the light-blocking layer 610. A difference value between a distance D44 between the second line WL2 and the first virtual central line VCL1, and a distance D33 between the first line WL1 and the first virtual central line VCL1, may be about equal to a value obtained by multiplying tan θ2 by a distance T2 between a lower surface of the line WL and the lower surface of the bank layer 123.

TABLE 1

| | Comparative | Comparative | Comparative | Embodiment | Embodiment | Embodiment |
|---|---|---|---|---|---|---|
| | Embodiment 1 | Embodiment 2 | Embodiment 3 | 1 | 2 | 3 |
| 20Tilt Angle | 0° | 30° | 45° | 0° | 30° | 45° |
| Transmission | 1.22 | 0.94 | 0.59 | 1.22 | 1.16 | 0.98 |
| rate (%) | | | | | | |

Table 1 shows light transmission rates of Comparative Embodiments in which a central line crossing the central point CP2 of the transmissive opening portion 610A and a central line crossing the central point CP1 of the second bank opening portion 123A correspond to each other, and, in comparison, shows light transmission rates of Embodiments in which the transmissive opening portion 610A is relatively shifted in a direction of the flat display area FDA and the second line WL2 is relatively shifted in a direction of the peripheral area PA. In detail, Table 1 shows the transmission rates with respect to angles by which the display panel is tilted according to the Comparative Embodiments and the transmission rates with respect to angles by which the display panel is tilted according to Embodiments.

Referring to Table 1, in the case of Comparative Embodiment 1 and Embodiment 1, in which the display panel is horizontally arranged, the transmission rates may be the same as each other at about 1.22%. However, in the case of Comparative Embodiment 2 and Embodiment 2, in which the display panel is tilted by 30°, the transmission rates may be about 0.94% and about 1.16%, respectively. Also, in the case of Comparative Embodiment 3 and Embodiment 3, in which the display panel is tilted by 45°, the transmission rates may be about 0.59% and about 0.98%, respectively. That is, when the transmissive opening portion 610A is shifted to be relatively adjacent to the flat display area FDA, and the second line WL2 is shifted to be relatively adjacent to the peripheral area PA, the light transmission rate may be improved.

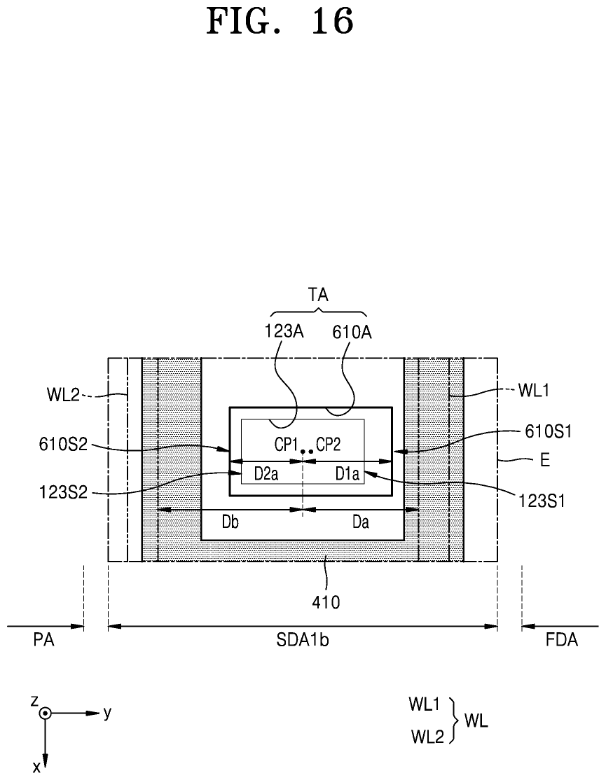

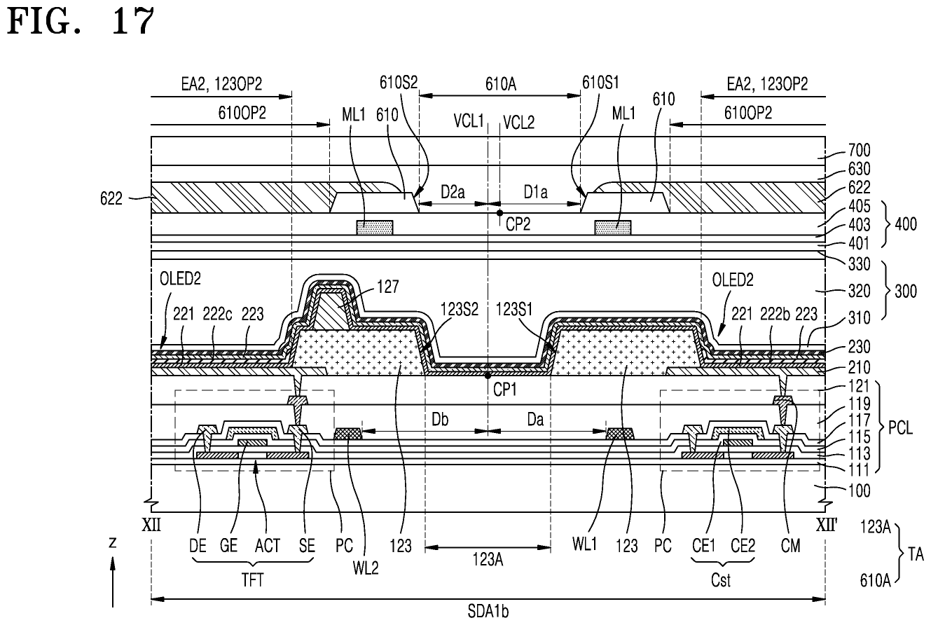

FIG. 16 is an enlarged view of the region “E” of FIG. 11, according to one or more other embodiments. FIG. 17 is a cross-sectional view of a display panel of FIG. 16 according to one or more embodiments, taken along the line XII-XII′ of FIG. 11. FIGS. 16 and 17 are modified embodiments of the one or more embodiments described with reference to FIGS. 11 to 14, and thus, the same or overlapping structure will not be described, and the aspects that are modified will be mainly described hereinafter.

Referring to FIGS. 16 and 17, the entire area of the transmissive opening portion 610A of the light-blocking layer 610 may overlap the second bank opening portion 123A of the bank layer 123.

According to one or more embodiments, the first sidewall 610S1 of the light-blocking layer 610 may be arranged to be adjacent to the flat display area FDA more than the first sidewall 123S1 of the bank layer 123. According to one or more embodiments, the second sidewall 610S2 of the light-blocking layer 610 may be arranged to be adjacent to the peripheral area PA more than the second sidewall 123S2 of the bank layer 123. A distance D1a between the first sidewall 610S1 of the light-blocking layer 610 and the first virtual central line VCL1 may be greater than a distance between the first sidewall 123S1 of the bank layer 123 and the first virtual central line VCL1. A distance D2a between the second sidewall 610S2 of the light-blocking layer 610 and the first virtual central line VCL1 may be greater than a distance between the second sidewall 123S2 of the bank layer 123 and the first virtual central line VCL1.

According to one or more embodiments, when an incident angle of incident light L is θ1 and a refraction angle is θ2, as illustrated in FIG. 15, a difference value between a distance D1a between the first sidewall 610S1 of the light-blocking layer 610 and the first virtual central line VCL1 and a distance D2a between the second sidewall 610S2 of the light-blocking layer 610 and the first virtual central line VCL1 may be about equal to twice a value obtained by multiplying tan θ2 by a distance between a lower surface of the bank layer 123 and a lower surface of the light-blocking layer 610, or may be about equal to the value obtained by multiplying tan θ2 by the distance between the lower surface of the bank layer 123 and the lower surface of the light-blocking layer 610.

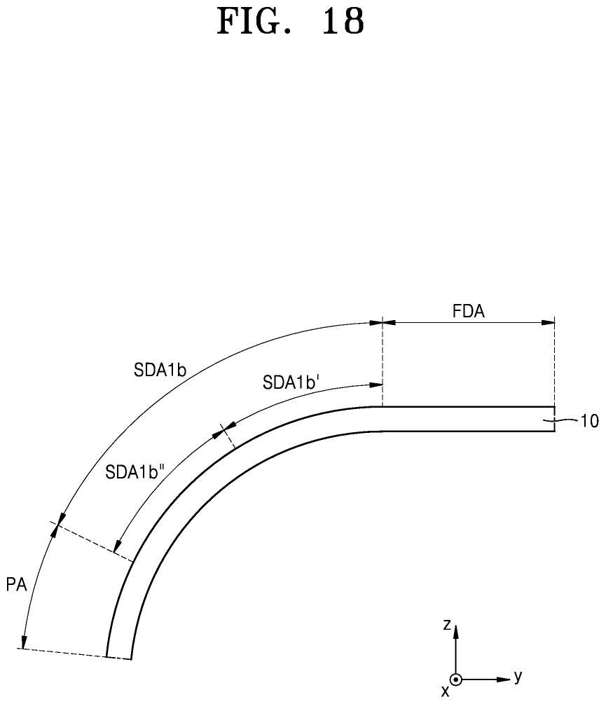

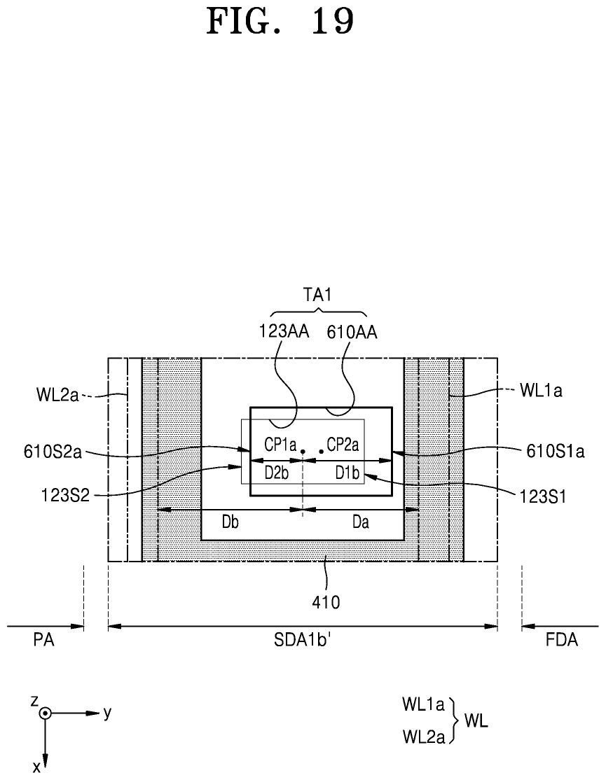

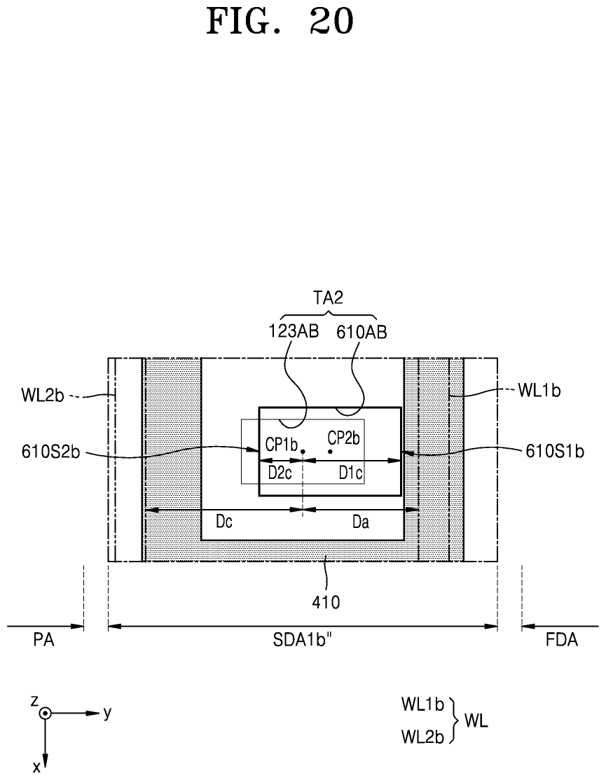

FIG. 18 is a schematic cross-sectional view of a display panel according to one or more embodiments. FIG. 18 illustrates that the 1st-2 side display area SDA1b, which is the component area, may include a first bending area SDA1b′ and a second bending area SDA1b″. FIGS. 19 and 20 are views of a transmission area in the first bending area SDA1b′ and a transmission area in the second bending area SDA1b″ of FIG. 18 according to one or more embodiments, the transmission areas corresponding to the region “E” of FIG. 11.

FIGS. 18 and 19 are modified embodiments of the one or more embodiments described with reference to FIGS. 11 to 14, and thus, the same structure will not be described, and the aspects that are modified will be mainly described hereinafter.

Referring to FIGS. 18 to 20, the 1st-2 side display area SDA1b may include the first bending area SDA1b′ arranged to be adjacent to the flat display area FDA, and the second bending area SDA1b″ arranged outside the first bending area SDA1b′. The second bending area SDA1b″ may be adjacent to the peripheral area PA. The first bending area SDA1b′ may be arranged between the second bending area SDA1b″ and the flat display area FDA. The second bending area SDA1b″ may be arranged between the first bending area SDA1b′ and the peripheral area PA.

When the 1st-2 side display area SDA1b includes the first bending area SDA1b′, and the second bending area SDA1b″ arranged outside the first bending area SDA1b′, each of the first bending area SDA1b′ and the second bending area SDA1b″ may include the transmission area. A distance between the first sidewall 610S1 (see FIG. 12) of the light-blocking layer 610 and a central line of the second bank opening portion 123A (see FIG. 12) may be greater in the second bending area SDA1b″ than in the first bending area SDA1b′. A difference between the distance between the first sidewall 610S1 (see FIG. 12) of the light-blocking layer 610 and the central line of the second bank opening portion 123A (see FIG. 12), and a distance between the second sidewall 610S2 (see FIG. 12) of the light-blocking layer 610 and the second bank opening portion 123A (see FIG. 12), may be greater in the second bending area SDA1b″ than in the first bending area SDA1b′. A difference between a distance between the second line WL2 (see FIG. 12) and the central line of the second bank opening portion 123A (see FIG. 12), and a distance between the first line WL1 (see FIG. 12) and the central line of the second bank opening portion 123A (see FIG. 12), may be greater in the second bending area SDA1b″ than in the first bending area SDA1b′.

The first bending area SDA1b′ may include a first transmission area TA1, and the second bending area SDA1b″ may include a second transmission area TA2, the first and second transmission areas TA1 and TA2 being different from each other. In the first bending area SDA1b′, the bank layer 123 (see FIG. 14) may include a 2nd-1 bank opening portion 123AA corresponding to the first transmission area TA1. In the first bending area SDA1b′, the light-blocking layer 610 (see FIG. 14) may include a first transmissive opening portion 610AA corresponding to the first transmission area TA1. In the second bending area SDA1b″, the bank layer 123 (see FIG. 14) may include a 2nd-2 bank opening portion 123AB corresponding to the second transmission area TA2. In the second bending area SDA1b″, the light-blocking layer 610 (see FIG. 14) may include a second transmissive opening portion 610AB corresponding to the second transmission area TA2. Planar shapes and cross-sectional shapes of the first bending area SDA1b′ and the second bending area SDA1b″ may be substantially the same as described with reference to FIG. 14, and thus, descriptions about the same aspects will be omitted, and different aspects will be mainly described.

A central point CP1a of the 2nd-1 bank opening portion 123AA arranged in the first bending area SDA1b′ may be defined as a point arranged at the right center in the 2nd-1 bank opening portion 123AA. A central point CP1b of the 2nd-2 bank opening portion 123AB arranged in the second bending area SDA1b″ may be defined as a point arranged at the right center in the 2nd-2 bank opening portion 123AB. A central point CP2a of the first transmissive opening portion 610AA arranged in the first bending area SDA1b′ may be defined as a point arranged at the right center in the first transmissive opening portion 610AA. A central point CP2b of the second transmissive opening portion 610AB arranged in the second bending area SDA1b″ may be defined as a point arranged at the right center in the second transmissive opening portion 610AB. Similar to the first virtual central line VCL1 described with reference to FIG. 14, a virtual central line of the 2nd-1 bank opening portion 123AA may be defined as a line crossing the central point CP1a of the 2nd-1 bank opening portion 123AA and arranged at the right center in the 2nd-1 bank opening portion 123AA. Similar to the first virtual central line VCL1 described with reference to FIG. 14, a virtual central line of the 2nd-2 bank opening portion 123AB may be defined as a line crossing the central point CP1b of the 2nd-2 bank opening portion 123AB and arranged at the right center in the 2nd-2 bank opening portion 123AB.

The first transmissive opening portion 610AA arranged in the first bending area SDA1b′ may be defined by a sidewall of the light-blocking layer 610 (see FIG. 11). In the first bending area SDA1b′, the light-blocking layer 610 may include a 1st-1 sidewall 610S1a and a 2nd-1 sidewall 610S2a facing each other. The 1st-1 sidewall 610S1a of the light-blocking layer 610 may be arranged to be adjacent to the flat display area FDA, based on the virtual central line crossing the central point CP1a of the 2nd-1 bank opening portion 123AA. The 2nd-1 sidewall 610S2a of the light-blocking layer 610 may be arranged to be adjacent to the peripheral area PA based on the virtual central line crossing the central point CP1a of the 2nd-1 bank opening portion 123AA.

The second transmissive opening portion 610AB arranged in the second bending area SDA1b″ may be defined by a sidewall of the light-blocking layer 610 (see FIG. 11). In the second bending area SDA1b″, the light-blocking layer 610 may include a 1st-2 sidewall 610S1b and a 2nd-2 sidewall 610S2b facing each other. The 1st-2 sidewall 610S1b of the light-blocking layer 610 may be arranged to be adjacent to the flat display area FDA, based on the virtual central line crossing the central point CP1b of the 2nd-2 bank opening portion 123AB. The 2nd-2 sidewall 610S2b of the light-blocking layer 610 may be arranged to be adjacent to the peripheral area PA, based on the virtual central line crossing the central point CP1b of the 2nd-2 bank opening portion 123AB.

A plurality of lines WL arranged in the first bending area SDA1b′ may include a 1st-1 line WL1a and a 2nd-1 line WL2a arranged to be adjacent to the first transmission area TA1 while not overlapping the first transmission area TA1. A plurality of lines WL arranged in the second bending area SDA1b″ may include a 1st-2 line WL1b and a 2nd-2 line WL2b arranged to be adjacent to the second transmission area TA2 while not overlapping the second transmission area TA2.

The central point CP2a of the first transmissive opening portion 610AA arranged in the first bending area SDA1b′ may be arranged to be closer to the flat display area FDA than the central point CP1a of the 2nd-1 bank opening portion 123AA. The central point CP2a of the second transmissive opening portion 610AB arranged in the second bending area SDA1b″ may be arranged to be closer to the flat display area FDA than the central point CP1b of the 2nd-2 bank opening portion 123AB. A distance between the central point CP2b of the second transmissive opening portion 610AB and the central point CP1b of the 2nd-2 bank opening portion 123AB in the second bending area SDA1b″ may be greater than a distance between the central point CP2a of the first transmissive opening portion 610AA and the central point CP1a of the 2nd-1 bank opening portion 123AA in the first bending area SDA1b′.

In an x-y plan view of the display panel in an unbent state, a difference between a distance D1c between the 1st-2 sidewall 610S1b of the light-blocking layer 610 and the central point CP1b of the 2nd-2 bank opening portion 123AB, and a distance D2c between the 2nd-2 sidewall 610S2b of the light-blocking layer 610 and the central point CP1b of the 2nd-2 bank opening portion 123AB in the second bending area SDA1b″, may be greater than a difference between a distance D1b between the 1st-1 sidewall 610S1a of the light-blocking layer 610 and the central point CP1a of the 2nd-1 bank opening portion 123AA, and a distance D2b between the 2nd-1 sidewall 610S2a of the light-blocking layer 610 and the central point CP1a of the 2nd-1 bank opening portion 123AA in the first bending area SDA1b′. The difference between the distance between the sidewall of the light-blocking layer 610, relatively adjacent to the flat display area, and the central point of the bank opening portion, and the distance between the sidewall of the light-blocking layer 610, relatively adjacent to the peripheral area, and the central point of the bank opening portion, may be greater in the second bending area SDA1b″ than in the first bending area SDA1b′. A difference between a distance D1c between the 1st-2 sidewall 610S1b of the light-blocking layer 610 and the virtual central line of the 2nd-2 bank opening portion 123AB, and a distance D2c between the 2nd-2 sidewall 610S2b of the light-blocking layer 610 and the virtual central line of the 2nd-2 bank opening portion 123AB in the second bending area SDA1b″, may be greater than a difference between a distance D1b between the 1st-1 sidewall 610S1a of the light-blocking layer 610 and the virtual central line of the 2nd-1 bank opening portion 123AA, and a distance D2b between the 2nd-1 sidewall 610S2a of the light-blocking layer 610 and the virtual central line of the 2nd-1 bank opening portion 123AA in the first bending area SDA1b′.

The first and second transmissive opening portions 610AA and 610AB of the light-blocking layer 610 may be shifted in a direction toward the flat display area FDA relatively more than the 2nd-1 and 2nd-2 bank opening portions 123AA and 123AB of the bank layer 123. According to one or more embodiments, a degree by which the 2nd-1 bank opening portion 123AA may be shifted in the direction toward the flat display area FDA in the first bending area SDA1b′ may be less than a degree by which the 2nd-2 bank opening portion 123AB may be shifted in the direction toward the flat display area FDA in the second bending area SDA1b″.

The 2nd-2 line WL2b arranged in the second bending area SDA1b″ may be adjacent to the peripheral area PA more than the 2nd-1 line WL2a arranged in the first bending area SDA1b′.

In an x-y plan view of the display panel in an unbent state, a difference between a distance Da between the 1st-2 line WL1b and the central point CP1b of the 2nd-2 bank opening portion 123AB, and a distance Dc between the 2nd-2 line WL2b and the central point CP1b of the 2nd-2 bank opening portion 123AB in the second bending area SDA1b″, may be greater than a difference between a distance Da between the 1st-1 line WL1a and the central point CP1a of the 2nd-1 bank opening portion 123AA, and a distance Dc between the 2nd-1 line WL2a the central point CP1a of the 2nd-1 bank opening portion 123AA in the first bending area SDA1b′. In the x-y plan view of the display panel in the unbent state, the distance Dc between the 2nd-2 line WL2b and the central point CP1b of the 2nd-2 bank opening portion 123AB in the second bending area SDA1b″ may be greater than the distance Db between the 2nd-1 line WL2a and the central point CP1a of the 2nd-1 bank opening portion 123AA in the first bending area SDA1b′.

The difference between the distance between the line WL relatively adjacent to the peripheral area PA and the central point of the bank opening portion and the distance between the line WL relatively adjacent to the flat display area FDA area and the central point of the bank opening portion may be greater in the second bending area SDA1b″ than in the first bending area SDA1b′.

FIGS. 18 to 20 illustrate that the 1st-2 side display area SDA1b may include two areas, but the 1st-2 side display area SDA1b is not limited thereto. The 1st-2 side display area SDA1b may include two or more areas. For example, the 1st-2 side display area SDA1b may include a first bending area adjacent to the flat display area FDA, a second bending area arranged outside the first bending area, and a third bending area arranged outside the second bending area. The first bending area may be arranged between the flat display area FDA and the second bending area, the second bending area may be arranged between the first bending area and the third bending area, and the third bending area may be arranged between the second bending area and the peripheral area PA. The third bending area may be adjacent to the peripheral area PA.

When the 1st-2 side display area SDA1b includes the first bending area adjacent to the flat display area FDA, the second bending area arranged outside the first bending area, and the third bending area arranged outside the second bending area, each of the first to third bending areas may include a transmission area. A distance between the first sidewall 610S1 (see FIG. 11) of the light-blocking layer 610 and the central line of the second bank opening portion 123A (see FIG. 11) may be greater in the second bending area than in the first bending area, and may be greater in the third bending area than in the second bending area.

FIGS. 18 to 20 illustrate that an area of the transmissive opening portion 610A may overlap the second bank opening portion 123A, according to one or more embodiments. However, the transmissive opening portion 610A is not limited thereto. According to one or more embodiments described with reference to FIGS. 16 and 17, the entire area of the transmissive opening portion 610A may overlap the second bank opening portion 123A.

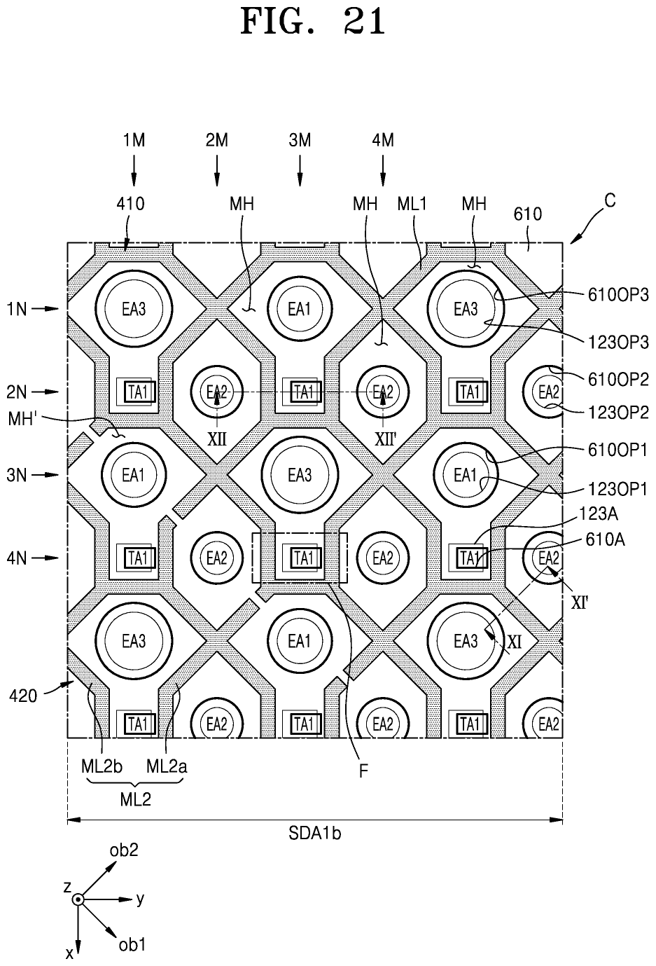

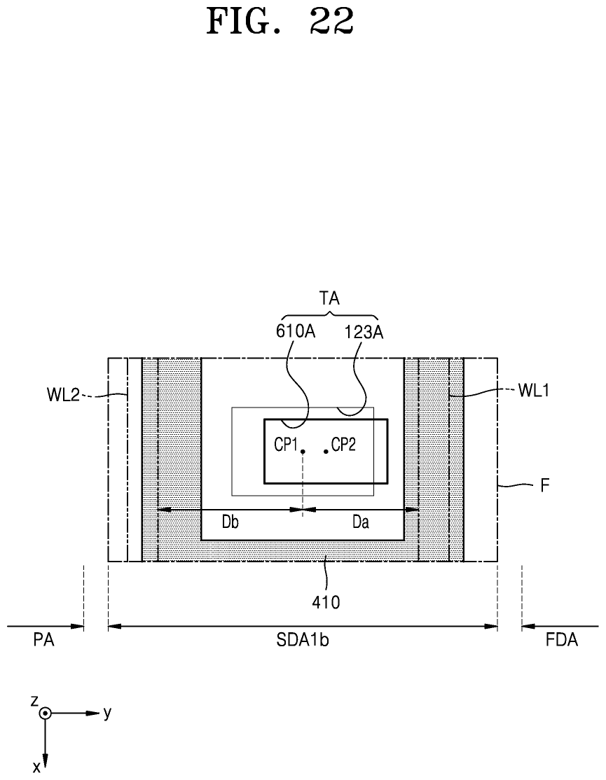

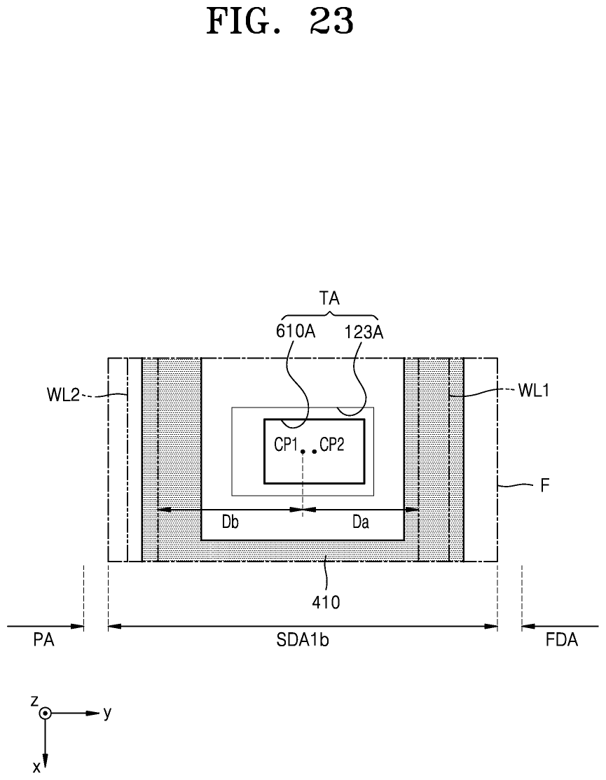

FIG. 21 is a plan view of the region “C” of the display panel of FIG. 3, according to one or more other embodiments. FIG. 22 is an enlarged view of a region “F” of FIG. 21, according to one or more embodiments. FIG. 23 is an enlarged view of the region “F” of FIG. 21, according to yet one or more other embodiments.

Referring to FIGS. 21 to 23, a size (or a width) of the transmissive opening portion 610A of the light-blocking layer 610 may be less than a size (or a width) of the second bank opening portion 123A of the bank layer 123. According to one or more embodiments, as illustrated in FIG. 22, a partial area of the transmissive opening portion 610A of the light-blocking layer 610 may overlap the second bank opening portion 123A of the bank layer 123. According to one or more other embodiments, as illustrated in FIG. 23, the entire area of the transmissive opening portion 610A of the light-blocking layer 610 may overlap the second bank opening portion 123A of the bank layer 123.

It is illustrated according to embodiments that the transmissive opening portion 610A of the light-blocking layer 610 may have a rectangular shape in the plan view, but the transmissive opening portion 610A of the light-blocking layer 610 is not limited thereto. For example, the transmissive opening portion 610A of the light-blocking layer 610 may be modified to have various shapes including a circular shape, an elliptical shape, or a polygonal shape.

It is illustrated according to embodiments that the second bank opening portion 123A of the bank layer 123 may have a rectangular shape in the plan view, but the second bank opening portion 123A of the bank layer 123 is not limited thereto. For example, the second bank opening portion 123A of the bank layer 123 may be modified to have various shapes including a circular shape, an elliptical shape, or a polygonal shape.

According to embodiments, the display panel may have improved visibility of the flat display area by arranging the component in the bending display area. According to embodiments, the amount of light transmitted through the opening portion of the transmission area may be increased by shifting or expanding the opening portion of the light-blocking layer arranged in the bending display area in a direction toward the flat display area. According to embodiments, the amount of light transmitted through the opening portion of the transmission area may be increased by shifting some of the lines arranged to be adjacent to the transmission area in a direction away from the flat display area. However, these aspects are examples, and the scope of the disclosure is not limited thereto.

It should be understood that embodiments described herein should be considered in a descriptive sense only and not for purposes of limitation. Descriptions of aspects within each embodiment should typically be considered as available for other similar aspects in other embodiments. While one or more embodiments have been described with reference to the figures, it will be understood by one of ordinary skill in the art that various changes in form and details may be made therein without departing from the spirit and scope as defined by the following claims, with functional equivalents thereof to be included therein.

What is claimed is:

1. A display panel comprising:
a display area comprising a flat display area, and a bending display area bending outside the flat display area;
a peripheral area outside the display area;
a substrate comprising emission areas in the flat display area and in the bending display area, and a transmission area between adjacent ones of the emission areas in the bending display area;
a pixel circuit layer on the substrate, and comprising a pixel circuit;
a light-emitting diode comprising a first electrode on the pixel circuit layer, an emission layer on the first electrode, and a second electrode on the emission layer;
a bank layer covering an edge of the first electrode, defining a first bank opening portion overlapping the first electrode, and defining a second bank opening portion corresponding to the transmission area; and
a light-blocking layer on the bank layer, and defining a transmissive opening portion corresponding to the transmission area,
wherein a central point of the transmissive opening portion of the light-blocking layer is closer to the flat display area than a central point of the second bank opening portion.

2. The display panel of claim 1, wherein the transmissive opening portion is defined by a sidewall of the light-blocking layer comprising a first sidewall and a second sidewall, the first sidewall being adjacent to the flat display area based on a first virtual central line crossing the central point of the second bank opening portion, and the second sidewall being adjacent to the peripheral area based on the first virtual central line, and
wherein a first distance between the first sidewall and the first virtual central line is greater than a second distance between the second sidewall and the first virtual central line.

3. The display panel of claim 2, wherein a partial area of the transmissive opening portion overlaps the second bank opening portion.

4. The display panel of claim 2, wherein an entire area of the transmissive opening portion overlaps the second bank opening portion.

5. The display panel of claim 2, wherein the bending display area comprises a first bending area adjacent to the flat display area, and a second bending area outside the first bending area, and
wherein a difference between the first distance and the second distance is greater in the second bending area than in the first bending area.

6. The display panel of claim 2, wherein the bending display area comprises a first bending area adjacent to the flat display area, a second bending area outside the first bending area, and a third bending area outside the second bending area, and
wherein a difference between the first distance and the second distance is greater in the second bending area than in the first bending area, and is greater in the third bending area than in the second bending area.

7. The display panel of claim 1, wherein the pixel circuit layer further comprises lines comprising a first line and a second line, the first line being adjacent to the transmission area in a direction away from a first virtual central line crossing the central point of the second bank opening portion toward the flat display area, and the second line being adjacent to the transmission area in a direction away from the first virtual central line toward the peripheral area, and
wherein a third distance between the first virtual central line and the first line is less than a fourth distance between the first virtual central line and the second line.

8. The display panel of claim 7, wherein the bending display area comprises a first bending area adjacent to the flat display area, and a second bending area outside the first bending area, and
wherein a difference between the fourth distance and the third distance is greater in the second bending area than in the first bending area.

9. The display panel of claim 1, wherein the flat display area comprises a first edge, a second edge, a third edge, and a fourth edge,
wherein the bending display area comprises a first side display area, a second side display area, a third side display area, and a fourth side display area that are bent by respectively extending from the first edge, the second edge, the third edge, and the fourth edge, and
wherein the transmission area is in the first side display area.

10. The display panel of claim 1, wherein a size of the transmissive opening portion is greater than a size of the second bank opening portion.

11. The display panel of claim 1, wherein a size of the transmissive opening portion is less than a size of the second bank opening portion.

12. The display panel of claim 1, further comprising an input-sensing layer between the bank layer and the light-blocking layer, and comprising touch electrodes comprising a conductive mesh pattern defining mesh holes,
wherein one of the emission areas in the bending display area and the transmission area are in a same mesh hole.

13. The display panel of claim 1, further comprising color filters in a first opening, a second opening, and a third opening overlapping the emission areas and defined by the light-blocking layer.

14. A display panel comprising:
a display area; comprising a flat display area, and a bending display area bending outside the flat display area;
a peripheral area outside the display area;
a substrate comprising emission areas in the flat display area and in the bending display area, and a transmission area between adjacent ones of the emission areas in the bending display area;
a pixel circuit layer on the substrate, and comprising a pixel circuit;
a light-emitting diode comprising a first electrode on the pixel circuit layer, an emission layer on the first electrode, and a second electrode on the emission layer;
a bank layer covering an edge of the first electrode, defining a first bank opening portion overlapping the first electrode, and defining a second bank opening portion corresponding to the transmission area;
an input-sensing layer on the bank layer and comprising touch electrodes; and
a light-blocking layer on the input-sensing layer, and defining a transmissive opening portion corresponding to the transmission area,
wherein the touch electrodes comprise a conductive mesh pattern defining mesh holes, and
wherein one of the emission areas in the bending display area and the transmission area are in a same mesh hole.

15. An electronic apparatus comprising a display panel, the display panel comprising:
a display area comprising a flat display area, and a bending display area bending outside the flat display area;
a peripheral area outside the display area;
a component below the display panel and in the bending display area;
a substrate comprising emission areas in the flat display area and the bending display area, and a transmission area between adjacent ones of the emission areas in the bending display area;
a pixel circuit layer on the substrate, and comprising a pixel circuit;
a light-emitting diode comprising a first electrode on the pixel circuit layer, an emission layer on the first electrode, and a second electrode on the emission layer;
a bank layer covering an edge of the first electrode, defining a first bank opening portion overlapping the first electrode, and defining a second bank opening portion corresponding to the transmission area; and
a light-blocking layer on the bank layer, and defining a first opening, a second opening, a third opening overlapping the emission areas, and defining a transmissive opening portion corresponding to the transmission area,
wherein a central point of the transmissive opening portion is closer to the flat display area than a first virtual central line crossing a central point of the second bank opening portion.

16. The electronic apparatus of claim 15, wherein the transmissive opening portion is defined by a sidewall of the light-blocking layer comprising a first sidewall adjacent to the flat display area based on the first virtual central line, and a second sidewall adjacent to the peripheral area based on the first virtual central line, and
wherein a first distance between the first sidewall and the first virtual central line is greater than a second distance between the second sidewall and the first virtual central line.

17. The electronic apparatus of claim 16, wherein the bending display area comprises a first bending area adjacent to the flat display area, and a second bending area closer to the peripheral area than the first bending area, and
wherein a difference between the first distance and the second distance is greater in the second bending area than in the first bending area.

18. The electronic apparatus of claim 15, wherein the pixel circuit layer further comprises lines comprising a first line below the bank layer and adjacent to the transmission area in a direction from the first virtual central line toward the flat display area, and a second line adjacent to the transmission area in a direction from the first virtual central line toward the peripheral area, and
wherein a third distance between the first virtual central line and the first line is less than a fourth distance between the first virtual central line and the second line.

19. The electronic apparatus of claim 15, wherein the component comprises a sensor using light.

20. The electronic apparatus of claim 15, wherein the flat display area comprises a first edge, a second edge, a third edge, and a fourth edge,
wherein the bending display area comprises a first side display area, a second side display area, a third side display area, and a fourth side display that are bent by respectively extending from the first edge, the second edge, the third edge, and the fourth edge, and
wherein the transmission area is in the first side display area.
